(19) United States
(12) Patent Application Publication
(10) Pub. No.: US 2022/0268942 A1
(43) Pub. Date: Aug. 25, 2022

(54) LIGHT RECEIVING DEVICE AND METHOD FOR DRIVING LIGHT RECEIVING DEVICE

(71) Applicant: SONY GROUP CORPORATION, TOKYO (JP)

(72) Inventors: SHUN KAIZU, TOKYO (JP); HAJIME MIHARA, TOKYO (JP)

(21) Appl. No.: 17/597,439

(22) PCT Filed: Jul. 2, 2020
(86) PCT No.: PCT/JP2020/025980

§ 371 Date: Jan. 6, 2022

(30) Foreign Application Priority Data
Jul. 16, 2019 (JP) 2019-130866

(51) Int. Cl. G01S 17/894; G01S 7/4863; G01S 7/4865; H04N 5/353; H04N 5/3745

(52) U.S. Cl. CPC G01S 17/894; G01S 7/4863; G01S 7/4865; H04N 5/353; H04N 5/3745

(57) ABSTRACT

The present technology relates to a light receiving device capable of expanding a measurement range, and a method of driving the light receiving device. The light receiving device includes a pixel having a photoelectric conversion unit that photoelectrically converts incident light to generate charges, a first charge accumulation unit that accumulates first charges generated in the photoelectric conversion unit for a first charge accumulation time, and a second charge accumulation unit that accumulates second charges generated in the photoelectric conversion unit for a second accumulation time different from the first accumulation time. The present technology can be applied to, for example, a ranging module that performs ranging using the indirect ToF method.

### TECHNICAL FIELD

The present technology relates to a light receiving device and a method for driving the light receiving device, and particularly, to a light receiving device capable of expanding a measurement range and a method for driving the light receiving device.

### BACKGROUND ART

Due to recent advances in semiconductor technology, some mobile terminals such as smartphones are equipped with a ranging module. As a ranging method in a ranging module, for example, there is an indirect Time of Flight (ToF) method. In the indirect ToF method, a ranging module radiates modulated light toward an object and detects light reflected from the surface of the object. At this time, the ranging module detects a phase difference between the radiated light and the reflected light by detecting the reflected light in four phases of 0 degrees, 90 degrees, 180 degrees, and 270 degrees with respect to the radiated light, for example, and converts the phase difference to a distance to the object.

For example, there is disclosed a distance imaging device having a configuration in which one pixel includes four charge accumulation parts and charges received with phase shifts of 0 degrees, 90 degrees, 180 degrees, and 270 degrees with respect to radiated light are allocated to the four charge accumulation units in the pixel (refer to PTL 1, for example).

### CITATION LIST

### Patent Literature

### [PTL 1]

### JP 2009-8537 A

### SUMMARY

### Technical Problem

It is difficult to widen a distance measurement range (dynamic range) of a ranging module using the indirect ToF method. That is, since radiated light attenuates in inverse proportion to the square of a distance, received luminance decreases as the distance increases, and the light is buried in noise. When the emission luminance of the radiated light is increased, charges are saturated at a short distance and thus the distance cannot be calculated.

The present technology has been made in view of such a situation and makes it possible to expand a measurement range.

### Solution to Problem

A light receiving device of one aspect of the present technology includes a pixel including a photoelectric conversion unit that photoelectrically converts incident light to generate charges, a first charge accumulation unit that accumulates first charges generated in the photoelectric conversion unit for a first accumulation time, and a second charge accumulation unit that accumulates second charges generated in the photoelectric conversion unit for a second accumulation time different from the first accumulation time.

A method for driving a light receiving device of one aspect of the present technology, by a driving control unit of the light receiving device including a pixel having a photoelectric conversion unit, a first charge accumulation unit, and a second charge accumulation unit, includes accumulating first charges generated in the photoelectric conversion unit for a first accumulation time in the first charge accumulation unit, and accumulating second charges generated in the photoelectric conversion unit for a second accumulation time different from the first accumulation time in the second charge accumulation unit.

In one aspect of the present technology, in a light receiving device including a pixel having a photoelectric conversion unit, a first charge accumulation unit, and a second charge accumulation unit, first charges generated in the photoelectric conversion unit for a first accumulation time are accumulated in the first charge accumulation unit, and second charges generated in the photoelectric conversion unit for a second accumulation time different from the first accumulation time are accumulated in the second charge accumulation unit.

The light receiving device may be an independent device or an internal block constituting one device.

### BRIEF DESCRIPTION OF DRAWINGS

FIG. 1 is a block diagram showing a configuration example of one embodiment of a ranging module to which the present technology is applied.

FIG. 2 is a diagram illustrating a schematic structure of a pixel in a pixel array part.

FIG. 3 is a diagram illustrating operation modes in which a ranging sensor can be executed.

FIG. 4 is a diagram illustrating calculation of a depth map in a normal driving mode.

FIG. 5 is a diagram illustrating calculation of a depth map in a normal driving mode.

FIG. 6 is a diagram illustrating calculation of a depth map in a normal driving mode.

FIG. 7 is a diagram showing a configuration example of a first pixel circuit of pixels.

FIG. 8 is a diagram illustrating an operation of the first pixel circuit in an HDR driving mode.

FIG. 9 is a diagram showing a configuration example of a second pixel circuit of the pixels.

FIG. 10 is a diagram illustrating an operation of the second pixel circuit in the HDR driving mode.

FIG. 11 is a diagram showing another driving example in which the HDR driving mode is realized in the second pixel circuit.

FIG. 12 is a block diagram showing a detailed configuration example of a signal processing unit.

FIG. 13 is a diagram illustrating correction processing executed by a correction processing unit.

FIG. 14 is a diagram illustrating correction processing executed by the correction processing unit.

FIG. 15 is a diagram illustrating depth map generation processing executed by a depth calculation unit.

FIG. 16 is a diagram illustrating depth map generation processing executed by the depth calculation unit.

FIG. 17 is a block diagram showing a first configuration example of a statistic calculation unit.

FIG. 18 is a block diagram showing a second configuration example of the statistic calculation unit.

FIG. 19 is a diagram illustrating a histogram of luminance values.

FIG. 20 is a diagram illustrating accumulation time calculation processing of an accumulation time calculation unit.

FIG. 21 is a flowchart of measurement processing for measuring a distance to an object in the HDR driving mode.

FIG. 22 is a diagram showing a chip configuration example of a ranging sensor.

FIG. 23 is a diagram illustrating a usage example of a ranging module.

FIG. 24 is a block diagram showing an example of a schematic configuration of a vehicle control system.

FIG. 25 is an explanatory diagram showing an example of installation positions of an external information detection unit and an imaging unit.

### DESCRIPTION OF EMBODIMENTS

Modes for embodying the present technology (hereinafter referred to as embodiments) will be described below. The description will be made in the following order.

1. Configuration example of ranging module
2. Schematic description of pixel
3. First circuit configuration example of pixel
4. Second circuit configuration example of pixel
5. Configuration example of signal processing unit
6. Correction processing in correction processing unit
7. Depth calculation processing in depth calculation unit
8. Statistic calculation processing in statistic calculation unit
9. Accumulation time calculation processing in accumulation time calculation unit
10. Measurement processing in HDR driving mode
11. Chip configuration example of ranging sensor
12. Usage example of ranging module
13. Example of application to moving body

### <1. Configuration Example of Ranging Module>

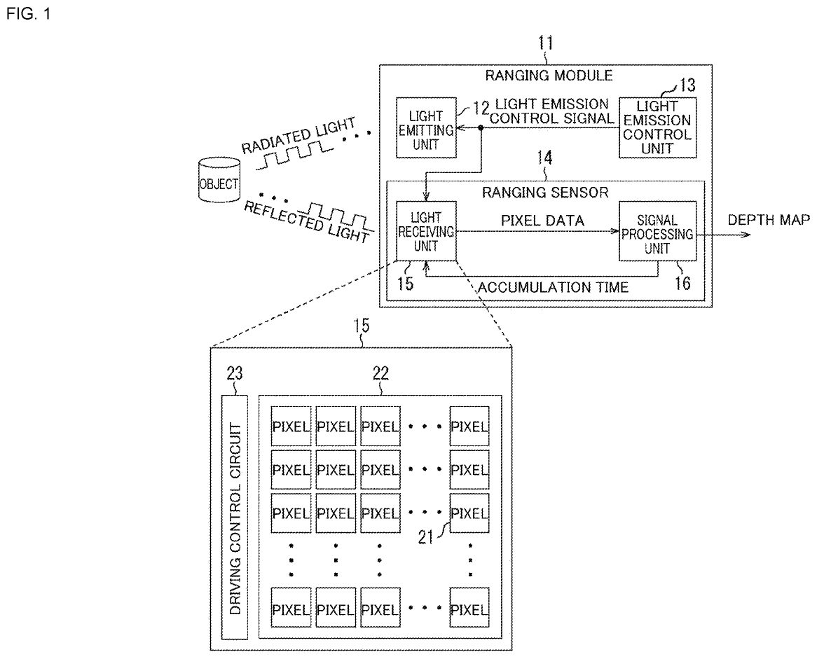

FIG. 1 is a block diagram showing a configuration example of one embodiment of a ranging module to which the present technology is applied.

The ranging module 11 shown in FIG. 1 performs ranging according to the indirect ToF method, and includes a light emitting unit 12, a light emission control unit 13, and a ranging sensor 14. The ranging module 11 radiates light to an object and receives light (reflected light) obtained by reflection of the radiated light from the object to generate a depth map as information on a distance to the object and output the depth map. The ranging sensor 14 is a light receiving device that receives reflected light and includes a light receiving unit 15 and a signal processing unit 16.

The light emitting unit 12 includes, for example, an infrared laser diode or the like as a light source, emits light while modulating the light at a timing in response to a light emission control signal supplied from the light emission control unit 13, and radiates the light to an object.

The light emission control unit 13 controls light emission of the light emitting unit 12 by supplying the light emission control signal with a predetermined frequency (for example, 20 MHz or the like) to the light emitting unit 12. Further, the light emission control unit 13 also supplies the light emission control signal to the light receiving unit 15 in order to drive the light receiving unit 15 in accordance with timing of light emission in the light emitting unit 12.

The light receiving unit 15 is provided with a pixel array part 22 in which pixels 21 that generate charges according to the amount of received light and output signals corresponding to the charges are two-dimensionally arranged in a matrix form in a row direction and a column direction, and a driving control circuit 23 is arranged in the peripheral area of the pixel array part 22.

The light receiving unit 15 is a pixel array part 22 in which a plurality of pixels 21 are two-dimensionally arranged and receives reflected light from an object.

Then, the light receiving unit 15 supplies the signal processing unit 16 with pixel data composed of a detection signal corresponding to the amount of reflected light received by each pixel 21 of the pixel array part 22.

The signal processing unit 16 calculates a depth value, which is a distance from the ranging module 11 to an object, for each pixel 21 of the pixel array part 22 on the basis of pixel data supplied from the light receiving unit 15, generates a depth map in which the depth value is stored as a pixel value of each pixel 21, and outputs the depth map to the outside of the module. Further, the signal processing unit 16 determines a charge accumulation time in each pixel 21 on the basis of the pixel data supplied from the light receiving unit 15 and supplies the charge accumulation time to the light receiving unit 15. As will be described later, the signal processing unit 16 may be configured as a separate chip (semiconductor chip) independent of the ranging sensor 14.

The driving control circuit 23 generates a control signal for controlling driving of the pixels 21 on the basis of, for example, the light emission control signal supplied from the light emission control unit 13, the accumulation time supplied from the signal processing unit 16, and the like and supplies the control signal to each pixel 21. The driving control circuit 23 drives each pixel 21 such that a light receiving period for which each pixel 21 receives reflected light corresponds to the accumulation time supplied from the signal processing unit 16.

### <2. Schematic Description of Pixel>

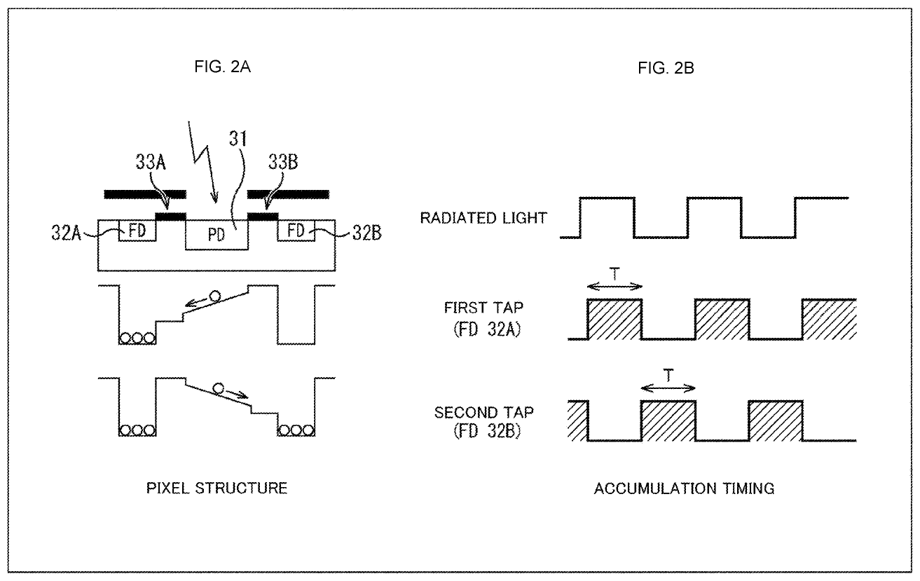

A schematic structure of each pixel 21 of the pixel array part 22 will be described with reference to FIG. 2.

As shown in A of FIG. 2, each pixel 21 of the pixel array unit 22 includes one photodiode (hereinafter referred to as PD), two FD 32 (32A and 32B), and two transfer transistors 33 (33A and 33B).

A in FIG. 2 shows a cross-sectional structure showing the arrangement of the PD 31, the FDs 32, and the transfer transistors 33 of the pixel 21, and a potential diagram.

One of the two FDs 32A and 32B, for example, the FD 32A, may be referred to below as a first tap 32A and the other FD 32B may be referred to as a second tap 32B. The two transfer transistors 33A and 33B are also referred to as the first transfer transistor 33A and the second transfer transistor 33B corresponding to the first tap 32A and the second tap 32B.

The PD 31 is a photoelectric conversion unit that photoelectrically converts incident light to generate charges, receives reflected light, and photoelectrically converts the reflected light to generate charges. The FD 32 is a charge accumulation unit that accumulates the charges generated by the photodiode 31. The transfer transistor 33 transfers the charges generated by the photodiode 31 to the FD 32.

The light (radiated light) emitted from the light emitting unit 12 of the ranging module 11 is reflected by a predetermined object that is a subject, is delayed by a predetermined phase, and is incident on the photodiode 31 of the light receiving unit 15 as reflected light.

As shown in B of FIG. 2, the driving control circuit 23 controls the first transfer transistor 33A to be in an active state (on) in a predetermined exposure period T such that charges generated by the photodiode 31 are transferred to the first tap 32A (FD 32A) and accumulated therein. When the first transfer transistor 33A is in the active state (on), the second transfer transistor 33B is controlled to be in an inactive state (off).

In the next exposure period T, the driving control circuit 23 controls the second transfer transistor 33B to be in the active state (on) such that the charges generated by the photodiode 31 are transferred to the second tap 32B (FD 32B) and accumulated therein. When the second transfer transistor 33B is in the active state (on), the first transfer transistor 33A is controlled to be in an inactive state (off).

The driving control circuit 23 alternately repeats on/off of opposite phases of the first transfer transistor 33A and the second transfer transistor 33B as described above. Among the charges generated by the photodiode 31, charges accumulated in the first tap 32A are output as a detection signal A and charges accumulated in the second tap 32B are output as a detection signal B.

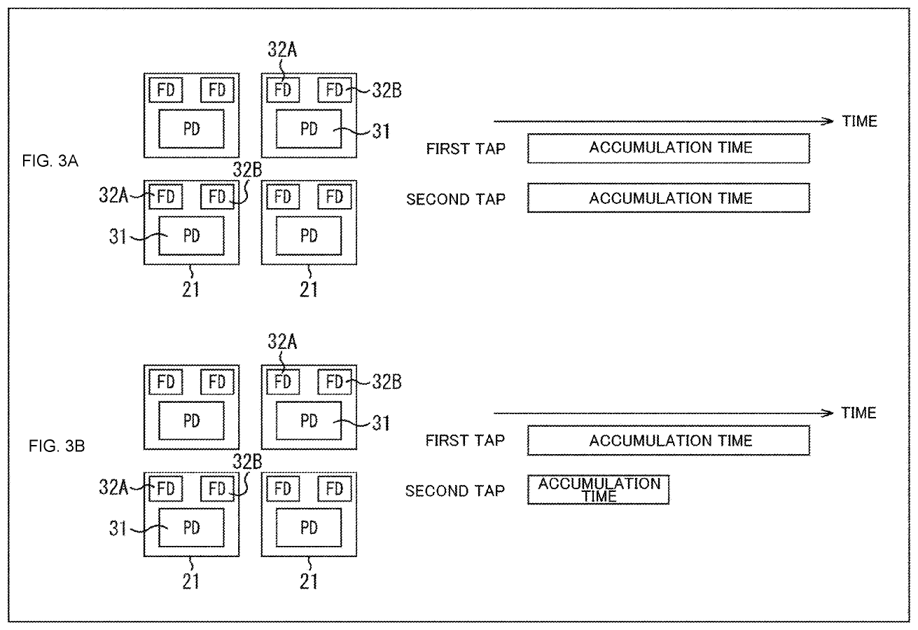

FIG. 3 is a diagram illustrating an operation mode in which the ranging sensor 14 can be executed.

The ranging sensor 14 can execute at least two operation modes, a first operation mode shown in A of FIG. 3 and a second operation mode shown in B of FIG. 3.

The first operation mode shown in A of FIG. 3 is a mode in which an accumulation time for accumulating charges in the first tap 32A and an accumulation time for accumulating charges in the second tap 32B are set to the same time, and a depth map is generated using detection signals detected by the two taps 32 at the same exposure time. Hereinafter, the first operation mode is also referred to as a normal driving mode.

On the other hand, the second operation mode shown in B of FIG. 3 is a mode in which the accumulation time for accumulating charges in the first tap 32A and the accumulation time for accumulating charges in the second tap 32B are set to different times, and a depth map is generated using detection signals detected by the two taps at different exposure times. The second operation mode is a mode in which a measurement range is expanded from a short distance to a long distance by calculating a distance using the detection signal in the first tap 32A having a long accumulation time with respect to a long-distance measurement range and calculating a distance using the detection signal in the second tap 32B having a short accumulation time with respect to a short-distance measurement range. Hereinafter, the second operation mode is also referred to as a high dynamic range (HDR) driving mode.

Although, in the two taps 32, the accumulation time of the first tap 32A is set to be longer and the accumulation time of the second tap 32B is set to be shorter (than the accumulation time of the first tap 32A) in the present embodiment, the relationship between the accumulation times of the two taps 32 may be opposite. Hereinafter, the accumulation time of the first tap 32A is also referred to as a first accumulation time or a long accumulation time, and the accumulation time of the second tap 32B is also referred to as a second accumulation time or a short accumulation time.

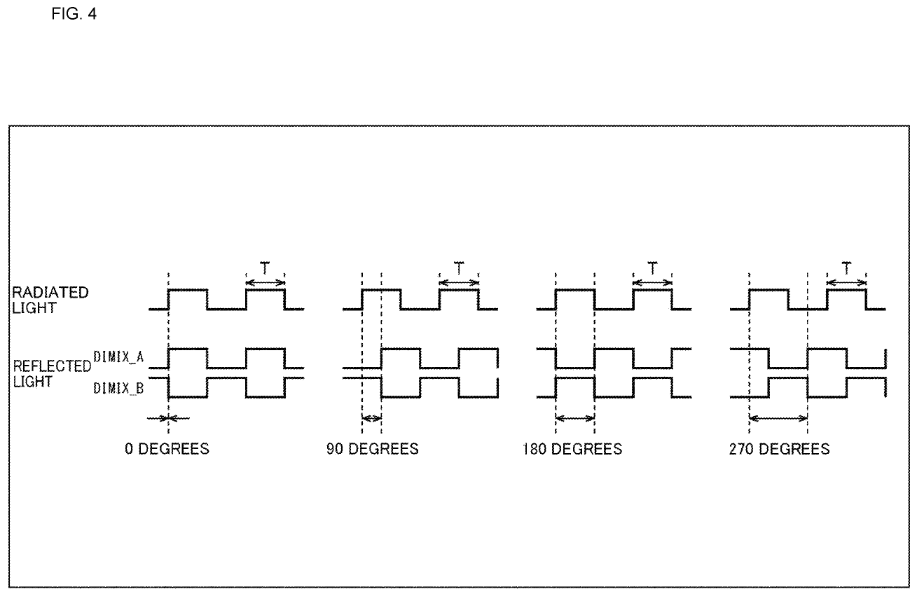

Next, calculation of a depth map in the basic normal driving mode will be described with reference to FIG. 4 to FIG. 6.

As shown in FIG. 4, a light emission control signal that repeats on/off in a radiation time T (1 cycle=2T) is supplied to the light emitting unit 12 from the light emission control unit 13. The light emitting unit 12 outputs radiated light such that on/off of radiation is repeated in the radiation time T.

The light receiving unit 15 receives reflected light at light receiving timings with phases shifted 0°, 90°, 180°, and 270° with respect to the radiation timing of the radiated light. More specifically, the light receiving unit 15 receives reflected light while changing phases in a time division manner in such a manner that it receives the reflected light with a phase set to 0° with respect to the radiation timing of the radiated light in a certain frame period, receives it with a phase set to 90° in the next frame period, receives it with a phase set to 180° in the next frame period, and receives it with a phase set to 270° in the next frame period.

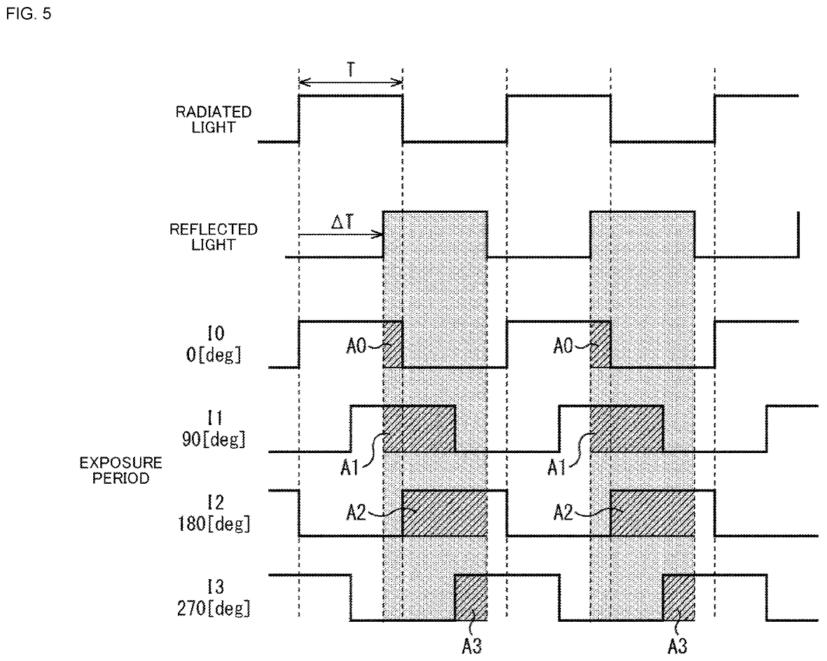

FIG. 5 is a diagram showing a reflected light arrival timing in the light receiving unit 15 and the accumulation time (exposure period) of the first tap 32A of the pixel 21 in each phase of 0°, 90°, 180°, and 270° side by side such that phase differences are easily ascertained.

As shown in FIG. 5, the reflected light is delayed by a delay time ΔT in response to a distance to an object, is incident on the photodiode 31, and is photoelectrically converted.

In the first tap 32A, it is assumed that a detection signal A obtained by receiving light in the same phase (phase 0°) as the radiated light is referred to as a detection signal A0, a detection signal A obtained by receiving light in a phase (phase 90°) shifted 90 degrees from the radiated light is referred to as a detection signal A1, a detection signal A obtained by receiving light in a phase (phase 180°) shifted 180 degrees from the radiated light is referred to as a detection signal A2, and a detection signal A obtained by receiving light in a phase (phase 270°) shifted 270 degrees from the radiated light is referred to as a detection signal A3.

The detection signals A0 to A3 are signals corresponding to the amount of light incident on the photodiode 31 for a period in which the reflected light is incident on the photodiode 31 and a period in which the first transfer transistor 33A is turned on.

Although not shown, a detection signal B obtained by receiving light in the same phase (phase 0°) as the radiated light is referred to as a detection signal B0, a detection signal B obtained by receiving light in a phase (phase 90°) shifted 90 degrees from the radiated light is referred to as a detection signal B1, a detection signal B obtained by receiving light in a phase (phase 180°) shifted 180 degrees from the radiated light is referred to as a detection signal B2, and a detection signal B obtained by receiving light in a phase (phase 270°) shifted 270 degrees from the radiated light is referred to as a detection signal B3 in the second tap 32B.

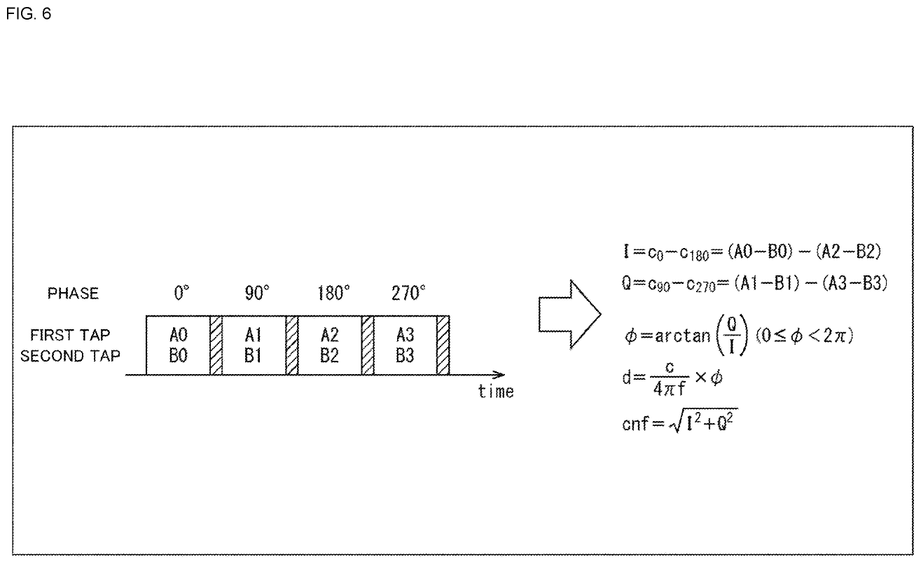

FIG. 6 is a diagram illustrating a method of calculating a depth value, which is a distance to an object, using detection signals detected with four phase differences.

In the indirect ToF method, a depth value d can be obtained by the following formula (1).

$$[ Math . 1 ]$$

$$d = \frac{c \cdot Δ T}{2} = \frac{c \cdot ϕ}{4 π f} \qquad ( 1 )$$

In formula (1), c is the speed of light, ΔT is a delay time, and f represents a modulation frequency of light. Further, φ in formula (1) represents a phase shift amount [rad] of reflected light and is represented by the following formula (2).

$$[ Math . 2 ]$$

$$ϕ = arc tan ( \frac{Q}{I} ) ( 0 \leq ϕ < 2 π ) \qquad ( 2 )$$

I and Q in formula (2) are calculated through the following formula (3) using the detection signals A0 to A3 and the detection signals B0 to B3 obtained by setting phases to 0°, 90°, 180° and 270°. I and Q are signals obtained by converting the phase of a cosine wave from polar coordinates to a Cartesian coordinate system (IQ plane) on the assumption that change in the luminance of radiated light is the cosine wave.

I=c₀−c₁₈₀=(A0−B0)−(A2−B2)

Q=c₉₀−c₂₇₀=(A1−B1)−(A3−B3) (3)

On the other hand, when a depth value d is calculated using only one of the two taps, for example, I and Q in formula (2) are calculated through the following formula (4) using the detection signals A0 to A3 and the detection signals B0 to B3 obtained by setting phases to 0°, 90°, 180°, and 270°.

I=c₀−c₁₈₀=(A0−A2)=(−B0+B2)

Q=c₉₀−c₂₇₀=(A1−A3)=(−B1+B3) (4)

Further, the reliability cnf of the pixel 21 can be obtained through the following formula (5).

[Math. 3]

cnf=\sqrt{I²+Q²} (5)

### <3. First Circuit Configuration Example of Pixel>

Next, a circuit configuration of the pixel 21 of the pixel array part 22 which can operate in both the normal driving mode and the HDR driving mode described above will be described.

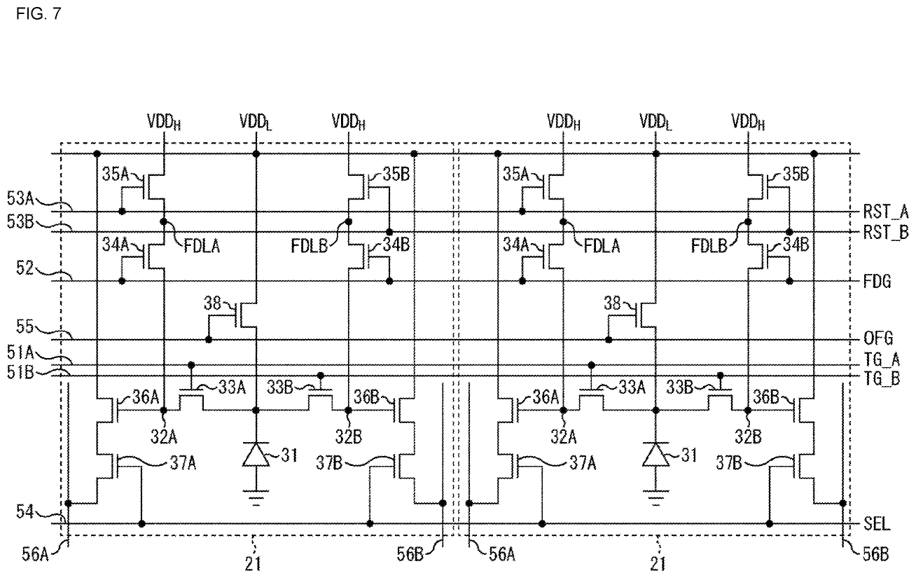

FIG. 7 shows a first circuit configuration example (first pixel circuit) of the pixel 21. Although the circuit configuration of two pixels adjacent to each other in the horizontal direction is shown in FIG. 7, the same applies to the other pixels 21.

As described above, the pixel 21 includes the PD 31, the two FDs 32A and 32B, and the first transfer transistors 33A and 33B. Further, the pixel 21 includes two switching transistors 34, two reset transistors 35, two amplification transistors 36, and two selection transistors 37 corresponding to the first tap 32A and the second tap 32B, and one discharge transistor 38.

Among the two switching transistors 34, the two reset transistors 35, the two amplification transistors 36, and the two selection transistors 37 provided in the pixel corresponding to the first tap 32A and the second tap 32B, those corresponding to the first tap 32A are referred to below as a first switching transistor 34A, a first reset transistor 35A, a first amplification transistor 36A, and a first selection transistor 37A, and those corresponding to the second tap 32B are referred to as a second switching transistor 34B, a second reset transistor 35B, a second amplification transistor 36B, and a second selection transistor 37B.

The transfer transistors 33, the switching transistors 34, the reset transistors 35, the amplification transistors 36, the selection transistors 37, and the discharge transistor 38 may be, for example, N-type MOS transistors (MOS FETs).

The first transfer transistor 33A becomes active in response to transition of a transfer driving signal TG_A supplied to the gate electrode thereof via a signal line 51A to High such that charges generated by the PD 31 are transferred to the first tap 32A (FD 32A) and accumulated therein. The second transfer transistor 33B becomes active in response to transition of a transfer driving signal TG_B supplied to the gate electrode thereof via a signal line 51B to High such that the charges generated by the PD 31 are transferred to the second tap 32B (FD 32B) and accumulated therein.

The first tap 32A (FD 32A) and the second tap 32B (FD 32B) are charge accumulation units that accumulate the charges transferred from the PD 31.

The first switching transistor 34A becomes active in response to transition of an FD driving signal FDG supplied to the gate electrode thereof via a signal line 52 to High such that an additional capacitance FDLA that is a source/drain region between the first switching transistor 34A and the first reset transistor 35A is connected to the first tap 32A (FD 32A). The second switching transistor 34B becomes active in response to transition of the FD driving signal FDG supplied to the gate electrode thereof via the signal line 52 to High such that an additional capacitance FDLB that is a source/drain region between the second switching transistor 34B and the second reset transistor 35B is connected to the second tap 32B (FD 32B).

The driving control circuit 23 connects the first tap 32A (FD 32A) to the additional capacitance FDLA and connects the second tap 32B (FD 32B) to the additional capacitance FDLB by setting the FD drive signal FDG to High, for example, in the case of high illuminance with a large amount of incident light. Accordingly, a larger amount of charges can be accumulated when the illuminance is high.

On the other hand, in the case of low illuminance with a small amount of incident light, the driving control circuit 23 separates the additional capacitances FDLA and FDLB from the first tap 32A (FD 32A) and the second tap 32B (FD 32B) by setting the FD driving signal FDG to Low. Accordingly, conversion efficiency can be improved.

The first reset transistor 35A becomes active in response to transition of a reset driving signal RST_A supplied to the gate electrode thereof via a signal line 53A to High such that the potential of the first tap 32A (FD 32A) is reset to a predetermined level (power supply voltage VDD_{H}). The second reset transistor 35B becomes active in response to transition of a reset driving signal RST_B supplied to the gate electrode thereof via a signal line 53B to High such that the potential of the second tap 32B (FD 32B) is reset to the predetermined level (power supply voltage VDD_{H}). When the first reset transistor 35A becomes active, the first switching transistor 34A also becomes active at the same time. As a result, charges accumulated in the first tap 32A (FD 32A) are discharged to the power supply voltage VDD_{H}. Similarly, when the second reset transistor 35B becomes active, the second switching transistor 34B also becomes active at the same time. As a result, charges accumulated in the second tap 32B (FD 32B) are discharged to the power supply voltage VDD_{H}.

The first amplification transistor 36A is connected to a constant current source that is not shown by connecting the source electrode thereof to a vertical signal line 56A via the first selection transistor 37A to constitute a source follower circuit. The second amplification transistor 36B is connected to the constant current source that is not shown by connecting the source electrode thereof to a vertical signal line 56B via the second selection transistor 37B to constitute a source follower circuit.

The first selection transistor 37A is connected between the source electrode of the first amplification transistor 36A and the vertical signal line 56A. The first selection transistor 37A becomes active in response to transition of a selection signal SEL supplied to the gate electrode thereof via a signal line 54 to High such that the detection signal A output from the first amplification transistor 36A is output to the vertical signal line 56A.

The second selection transistor 37B is connected between the source electrode of the second amplification transistor 36B and the vertical signal line 56B. The second selection transistor 37B becomes active in response to transition of the selection signal SEL supplied to the gate electrode thereof via the signal line 54 to High such that the detection signal B output from the second amplification transistor 36B is output to the vertical signal line 56B.

The discharge transistor 38 becomes active in response to transition of a discharge signal OFG supplied to the gate electrode thereof via a signal line 55 to High such that charges generated and held by the PD 31 are discharged to a predetermined power supply voltage VDD_{L}. The power supply voltage VDD_{H} and the power supply voltage VDD_{L} may have different power supply voltage levels or may have the same power supply voltage level.

The signal lines 51 to 54 of the pixel 10 are connected to the driving control circuit 23, and the transfer transistors 33, the switching transistors 34, the reset transistors 35, the selection transistors 37, and the discharge transistor 38 are controlled by the driving control circuit 23

Although the additional capacitances FDLA and FDLB and the first switching transistor 34A and the second switching transistor 34B that control connection thereof may be omitted in the first pixel circuit of FIG. 7, it is possible to secure a wide dynamic range by properly using the additional capacitances FDLA and FDLB in response to the amount of incident light.

The basic operation from reception of incident light to output of a detection signal will be briefly described using an example of the first tap 32A (FD 32A) of the pixel 21.

First, a reset operation of resetting charges of the pixel 21 is performed before the start of reception of light. That is, the first reset transistor 35A, the first switching transistor 34A, and the discharge transistor 38 are turned on, and charges accumulated in the PD 31, the first tap 32A (FD 32A), and the additional capacitance FDLA are reset by being connected to the power supply voltage VDD_{H} or the power supply voltage VDD_{L}.

After resetting the charges, reception of light is started. That is, when light (reflected light) is incident on the PD 31, it is photoelectrically converted in the PD 31 to generate charges.

When the high transfer driving signal TG_A is supplied to the first transfer transistor 33A via the signal line 51A, the first transfer transistor 33A transfers the charges generated by the PD 31 to the first tap 32A (FD 32A) such that they are accumulated therein.

Then, when the high selection signal SEL is supplied to the first selection transistor 37A via the signal line 54 after a lapse of a certain period of time, a detection signal A corresponding to a potential accumulated in the first tap 32A (FD 32A) is output to the vertical signal line 56A via the first selection transistor 37A.

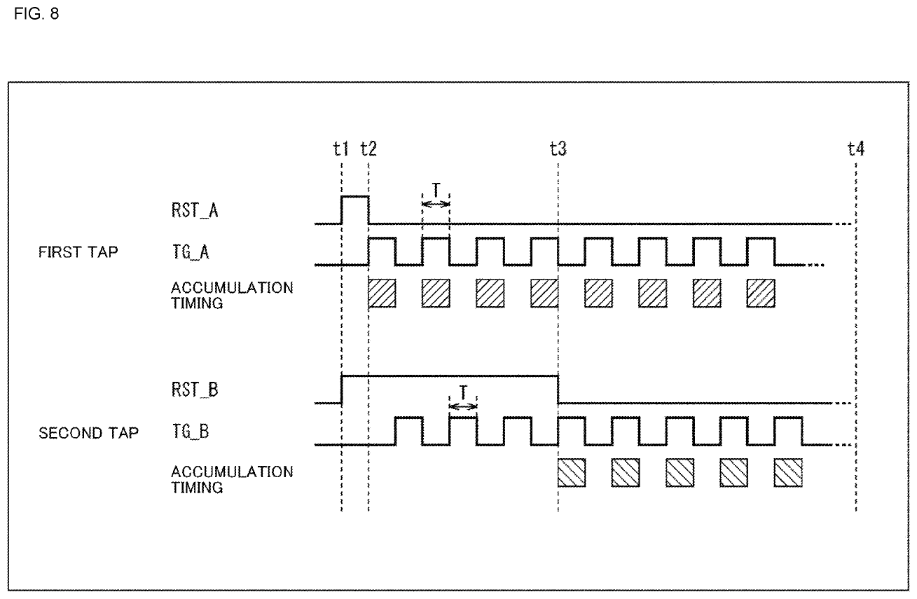

Next, the operation of the first pixel circuit in the HDR driving mode will be described with reference to FIG. 8.

First, at time t1, the reset driving signals RST_A and RST_B are controlled to be High, and charges accumulated in the first tap 32A (FD 32A) and the second tap 32B (FD 32B) are reset.

At time t2, the reset driving signal RST_A is controlled to be Low. On the other hand, the reset driving signal RST_B is maintained at High until time t3.

Further, after time t2, the driving control circuit 23 outputs the transfer driving signals TG_A and TG_B that alternately repeat on/off of opposite phases of the first transfer transistor 33A and the second transfer transistor 33B in an exposure period T.

In the first tap 32A (FD 32A) in which the reset driving signal RST_A is controlled to be Low, charges generated by the PD 31 are transferred to the first tap 32A and accumulated therein in a period in which the transfer driving signal TG_A is set to High after time t2.

On the other hand, in the second tap 32B (FD 32B), charges generated by the PD 31 for a period in which the transfer driving signal TG_B is set to High are discharged to the power supply voltage VDD_{H} and are not accumulated because the reset driving signal RST_B is set to High from time t2 to time t3.

After the reset driving signal RST_B is set to Low at time t3, charges generated by the PD 31 for a period in which the transfer driving signal TG_B is set to High are transferred to the second tap 32B and accumulated therein.

From time t3 to time t4 after a lapse of a certain period of time, control of alternately repeating on/off of the opposite phases of the first transfer transistor 33A and the second transfer transistor 33B in the exposure period T is continued.

The accumulation time (first accumulation time) on the side of the first tap 32A of the first pixel circuit corresponds to a time in which the first reset transistor 35A is in an inactive state and the first transfer transistor 33A is controlled to be in an active state during the period from time t2 to time t4. On the other hand, the accumulation time (second accumulation time) on the side of the second tap 32B of the first pixel circuit corresponds to a time in which the second reset transistor 35B is in an inactive state and the second transfer transistor 33B is controlled to be in an active state during the period from time t2 to time t4. On the side of the second tap 32B, the period in which the second reset transistor 35B is controlled to be in the active state is longer than that on the side of the first tap 32A, and the second accumulation time is shorter than the first accumulation time because charges transferred to the second tap 32B are discarded while the second reset transistor 35B is controlled to be in the active state.

As described above, in the HDR driving mode of the first pixel circuit, the accumulation time of the first tap 32A and the accumulation time of the second tap 32B are controlled to be different times by changing a time for which the first reset transistor 35A is in an active state and a time for which the second reset transistor 35B is in an active state.

The normal driving mode can be realized by controlling the reset driving signal RST_B to be Low like the reset driving signal RST_A at time t2 during driving of the HDR driving mode described above.

### <4. Second Circuit Configuration Example of Pixel>

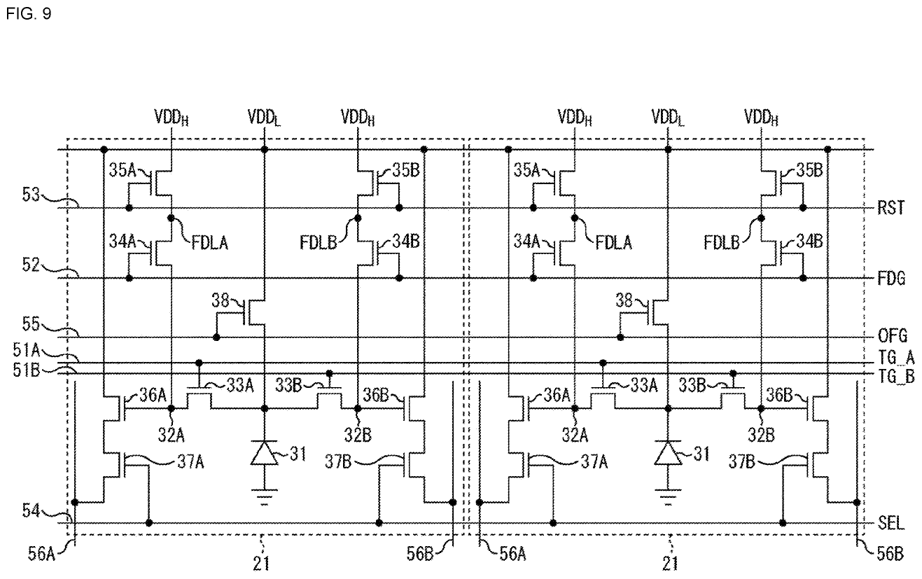

FIG. 9 shows a second circuit configuration example (second pixel circuit) of the pixel 21.

The second pixel circuit of FIG. 9 shows a circuit configuration of two pixels adjacent to each other in the horizontal direction, similarly to the first pixel circuit shown in FIG. 7, and parts that are the same as those of FIG. 7 are denoted by the same signs and description thereof is omitted as appropriate.

In the second pixel circuit of FIG. 9, wiring of the signal line 53 that controls the reset transistor 35 is different from that of the first pixel circuit of FIG. 7.

That is, in the first pixel circuit of FIG. 7, two signal lines 53A and 53B are provided for one pixel 21 (pixel row), the first reset transistor 35A is controlled by the reset driving signal RST_A supplied via the signal line 53A, and the second reset transistor 35B is controlled by the reset driving signal RST_B supplied via the signal line 53B.

On the other hand, the second pixel circuit of FIG. 9 has a configuration in which one signal line 53 is provided for one pixel 21 (pixel row), and the first reset transistor 35A and the second reset transistor 35B are controlled by a reset driving signal RST supplied via the common signal line 53.

Other configurations of the second pixel circuit of FIG. 9 are the same as the first pixel circuit of FIG. 7.

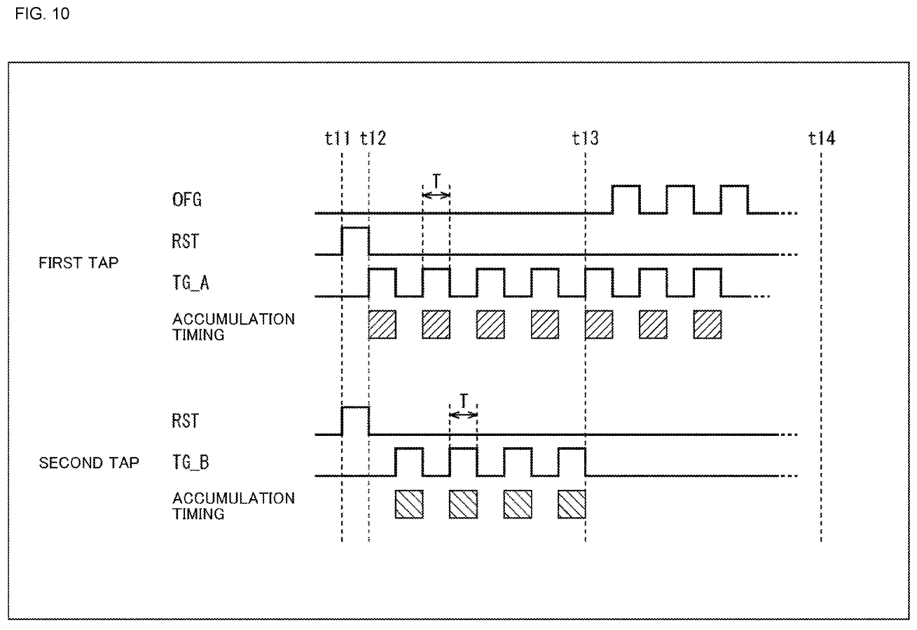

The operation of the second pixel circuit in the HDR driving mode will be described with reference to FIG. 10.

First, at time t11, the reset driving signal RST is controlled to be High, and charges accumulated in the first tap 32A (FD 32A) and the second tap 32B (FD 32B) are reset.

At time t12, the reset driving signal RST is controlled to be Low.

Further, after time t12, the driving control circuit 23 outputs the transfer driving signals TG_A and TG_B that alternately repeat on/off of opposite phases of the first transfer transistor 33A and the second transfer transistor 33B in an exposure period T.

In the first tap 32A (FD 32A), charges generated by the PD 31 are transferred to the first tap 32A and accumulated therein in a period in which the transfer driving signal TG_A is set to High. Further, in the second tap 32B (FD 32B), charges generated by the PD 31 are transferred to the second tap 32B and accumulated therein in a period in which the transfer driving signal TG_B is set to High.

From time t12 to time t13, the operation of alternately accumulating the charges generated by the PD 31 in the first tap 32A and the second tap 32B is repeated.

After time t13, the driving control circuit 23 is changed to control the transfer driving signal TG_B to be Low in the period in which the transfer driving signal TG_B has been controlled to be High and controls the discharge signal OFG supplied to the discharge transistor 38 via the signal line 55 to be High.

As a result, control of alternately repeating on/off of the opposite phases of the first transfer transistor 33A and the discharge transistor 38 in the exposure period T is executed in a period from the time t13 to the time t14.

The accumulation time (first accumulation time) on the side of the first tap 32A of the second pixel circuit corresponds to a time in which the first transfer transistor 33A is controlled to be in an active state in the period from time t12 to time t14. On the other hand, the accumulation time (second accumulation time) on the side of the second tap 32B of the second pixel circuit corresponds to a time in which the second transfer transistor 33B is controlled to be in an active state in the period from time t12 to time t14. However, the second accumulation time is shorter than the first accumulation time because there is a period from time t13 to time t14 in which the discharge transistor 38 is controlled to be in an active state instead of the second transfer transistor 33B being controlled to be in an active state.

The normal driving mode can be realized by continuing the control during the period from time t12 to time t13 even in the period from time t13 to time t14 in the operation of the HDR driving mode described above. In other words, in the HDR driving mode of the second pixel circuit, a part of the exposure period of the normal driving mode of the second pixel circuit is changed from a period for accumulation of charges in the second tap 32B to a period for discharge of charges by the discharge transistor 38.

As described above, in the HDR driving mode of the second pixel circuit, the accumulation time of the first tap 32A and the accumulation time of the second tap 32B are controlled to be different times by changing a part of the period in which charges are accumulated in the second tap 32B in the normal driving mode to a period for driving for controlling the discharge transistor 38 to be in an active state.

In the HDR driving mode of the first pixel circuit shown in FIG. 8, an accumulation start timing at which charge accumulation is started differs between the first tap 32A and the second tap 32B, and an accumulation end timing at which charge accumulation ends is approximately the same (a deviation of exposure time T). In this case, when charges are saturated in the first tap 32A having a long accumulation time, charges are likely to leak to the second tap 32B which starts accumulation with a delay.

On the other hand, in the HDR driving mode of the second pixel circuit, the accumulation start timing at which charge accumulation is started is approximately the same in the first tap 32A and the second tap 32B (a deviation of the exposure time T), and the accumulation end timing at which charge accumulation ends differs therebetween. In this case, even if charges are saturated in the first tap 32A having a long accumulation time after completion of accumulation in the second tap 32B, charges are unlikely to leak to the second tap 32B because charges generated by the PD 31 are discarded by the discharge transistor 38.

In the second pixel circuit, the HDR driving mode can be realized in an operation other than the driving operation described with reference to FIG. 10.

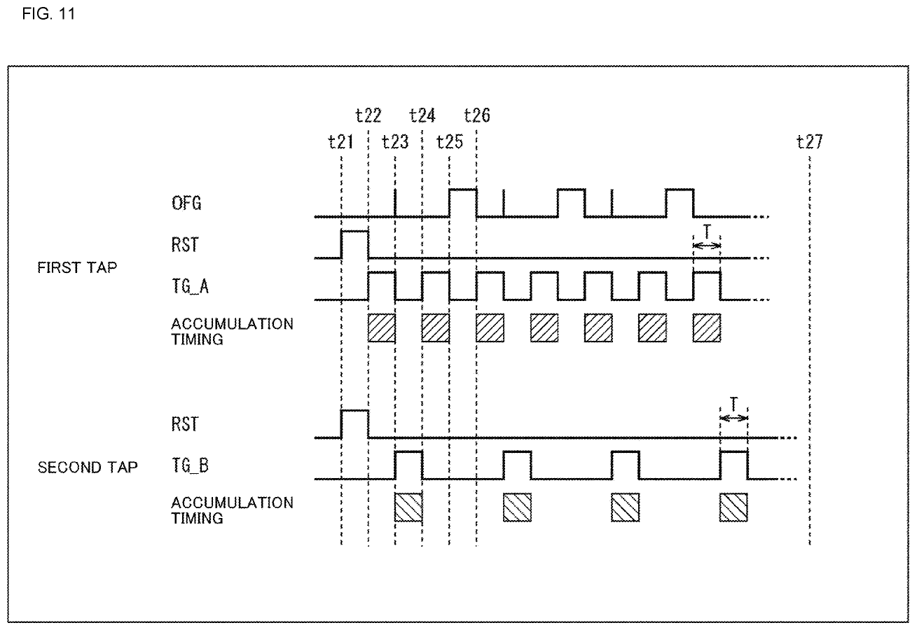

FIG. 11 is a diagram showing another operation example in which the HDR driving mode is realized in the second pixel circuit as a modified example of the HDR driving mode of the second pixel circuit.

The operation described with reference to FIG. 10 is assumed to be an operation in which the accumulation start timing at which accumulation of charges is started is approximately the same in the first tap 32A and the second tap 32B, and the second tap 32B accumulates charges in the first half of the entire accumulation period. In this case, since the accumulation period of the second tap 32B is concentrated on the first half of the entire accumulation period, the simultaneity of the accumulation time points in the first tap 32A and the second tap 32B is collapsed. For example, when a subject is a moving object and movement differs between the first half and the second half of the entire accumulation period, detection results are different in the first tap 32A and the second tap 32B.

Therefore, in the modified example of the HDR driving mode in the second pixel circuit of FIG. 11, the driving control circuit 23 performs driving with improved simultaneity of accumulation time points in the first tap 32A and the second tap 32B.

Specifically, the driving control circuit 23 performs control such that one charge accumulation in the second tap 32B is executed with respect to a plurality of charge accumulations in the first tap 32A. FIG. 11 shows an example in which charge accumulation is executed once in the second tap 32B each time charges are accumulated in the first tap 32A twice.

That is, at time t21, the reset driving signal RST is controlled to be High and charges accumulated in the first tap 32A and the second tap 32B are reset.

At time t22, the reset driving signal RST is controlled to be Low.

Further, in the period from time t22 to time t23, the driving control circuit 23 controls the transfer driving signal TG_A to be High to turn on the first transfer transistor 33A and controls the transfer driving signal TG_B to be Low to turn off the second transfer transistor 33B.

At the next time t23, the driving control circuit 23 changes the transfer driving signal TG_A to Low to turn off the first transfer transistor 33A and instantaneously controls the discharge signal OFG to be High to turn off the discharge transistor 38 for a short period of time. Then, after the discharge transistor 38 is turned off, the driving control circuit 23 controls the transfer driving signal TG_B to be High to turn on the second transfer transistor 33B until time t24.

In the next period from the time t24 to time t25, the driving control circuit 23 controls the transfer driving signal TG_A to be High to turn on the first transfer transistor 33A and controls the transfer driving signal TG_B to be Low to turn off the second transfer transistor 33B.

In the next period from the time t25 to time t26, the driving control circuit 23 turns off the first transfer transistor 33A according to the Low transfer driving signal TG_A and turns on the discharge transistor 38 according to the High discharge signal OFG.

In the period from time t22 to time t26, accumulation of charges in the first tap 32A is executed twice. Accumulation of charges in the second tap 32B is executed after the first accumulation of charges in the first tap 32A, and discharge of charges by the discharge transistor 38 is executed after the second accumulation of charges in the first tap 32A. Accordingly, each time charges are accumulated in the first tap 32A twice, charges are accumulated in the second tap 32B once.

Further, the discharge transistor 38 is controlled to be in an active state for a short time such that charges are discharged between accumulation of charges in the first tap 32A and accumulation of charges in the second tap 32B. By constantly performing discharge of charges by the discharge transistor 38 after accumulation of charges in the first tap 32A, characteristics of charge transfer to the first tap 32A are prevented from varying depending on presence or absence of accumulation of charges in the second tap 32B to stabilize the characteristics.

From time t26 to time t27, the same operation as that described above performed from time t22 to time t26 is repeated a plurality of times.

According to the above-described modified example of the HDR driving mode of the second pixel circuit, it is possible to control the first accumulation time on the side of the first tap 32A and the second accumulation time on the side of the second tap 32B such that they are different from each other and to improve simultaneity of accumulation time points by executing accumulation of charges in the second tap 32B once each time charges are accumulated in the first tap 32A a plurality of times. Due to high simultaneity of accumulation time points, moving subject characteristics are improved.

Although phases have not been particularly mentioned in the operations of the first pixel circuit and the second pixel circuit described with reference to FIG. 7 to FIG. 11, pixel data is obtained with respect to four phases, as described with reference to FIG. 4 to FIG. 6. That is, the pixel 21 controls the first accumulation time of the first tap 32A and the second accumulation time of the second tap 32B such that they are different from each other and accumulates charges for four phases shifted 0°, 90°, 180°, and 270° with respect to the radiation timing of radiated light, and outputs the detection signals A0 to A3 and the detection signals B0 to B3.

The above-described first pixel circuit or second pixel circuit is adopted for the pixels 21 arranged in the pixel array part 22 of the light receiving unit 15, and the detection signals A0 to A3 depending on charges accumulated in the first tap 32A in the first accumulation time (long accumulation time) and the detection signals B0 to B3 depending on charges accumulated in the second tap 32B in the second accumulation time (short accumulation time) are converted into digital values by an AD conversion unit that is not shown and output as pixel data to the signal processing unit 16 in the subsequent stage according to the operation of the HDR driving mode described above.

### <5. Configuration Example of Signal Processing Unit>

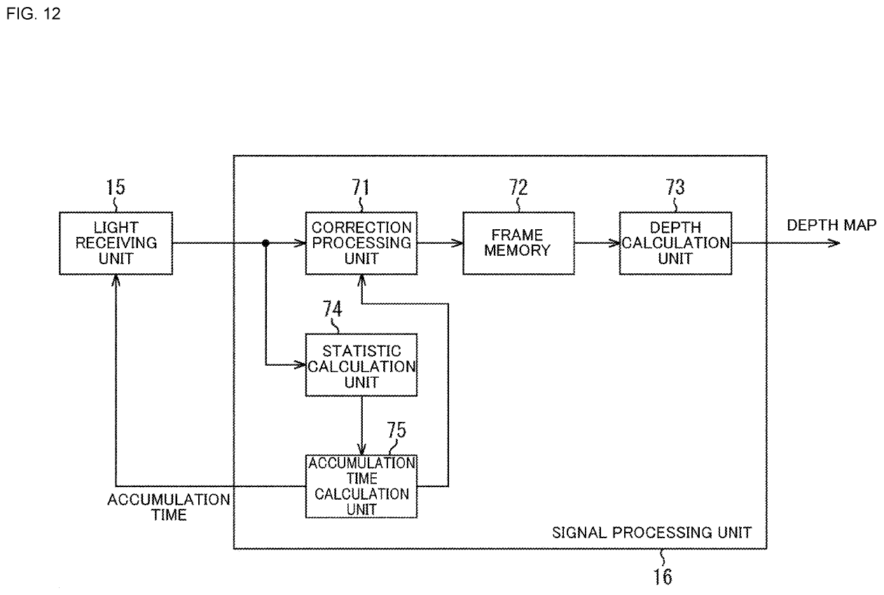

FIG. 12 is a block diagram showing a detailed configuration example of the signal processing unit 16.

The signal processing unit 16 includes a correction processing unit 71, a frame memory 72, a depth calculation unit 73, a statistic calculation unit 74, and an accumulation time calculation unit 75.

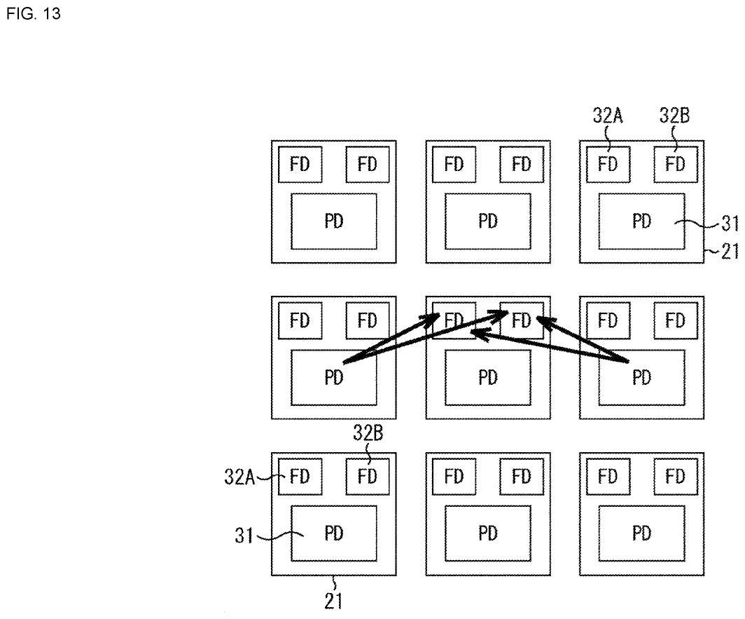

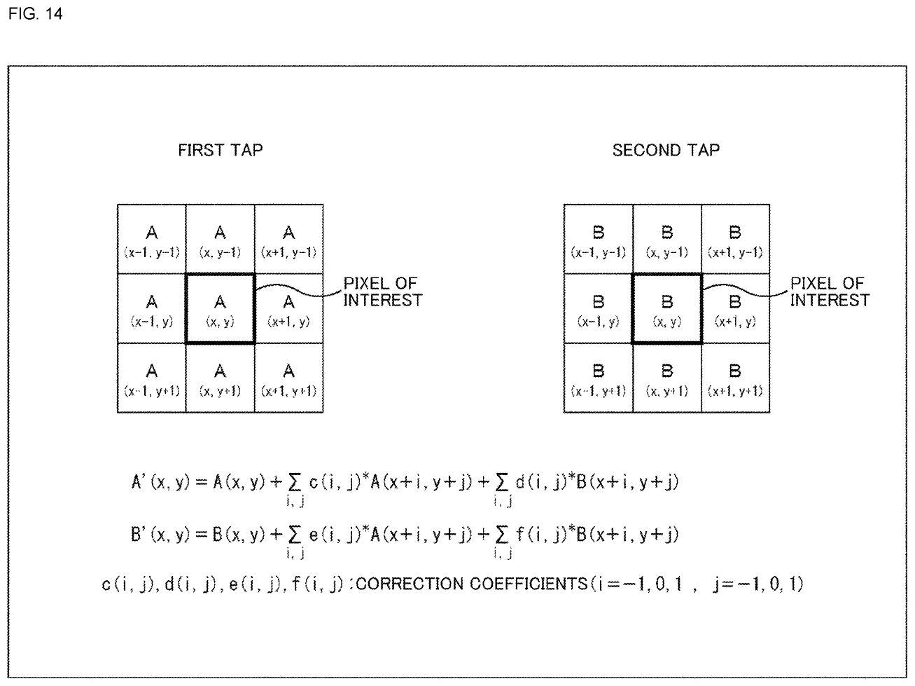

Pixel data of each pixel 21 is supplied to the correction processing unit 71 from the light receiving unit 15, and accumulation time when the pixel data has been acquired is supplied from the accumulation time calculation unit 75 thereto. The correction processing unit 71 regards each pixel 21 of the pixel array part 22 as a pixel of interest and executes correction processing of correcting pixel data of the pixel of interest using pixel data of peripheral pixels around the pixel of interest. Details of correction process will be described later with reference to FIG. 13 and FIG. 14.

The frame memory 72 is sequentially supplied with pixel data of the pixels 21 processed by the correction processing unit 71, specifically, detection signals A and detection signals B with phases of 0°, 90°, 180°, and 270°. Here, the detection signals A are signals corresponding to charges accumulated in the first tap 32A in the first accumulation time (long accumulation time) and the detection signals B are signals corresponding to charges accumulated in the second tap 32B in the second accumulation time (short accumulation time).

The frame memory 72 stores the detection signals A and the detection signals B with the phases 0°, 90°, 180°, and 270° of each pixel 21 as data of one frame and supplies the data to the depth calculation unit 73 as necessary.

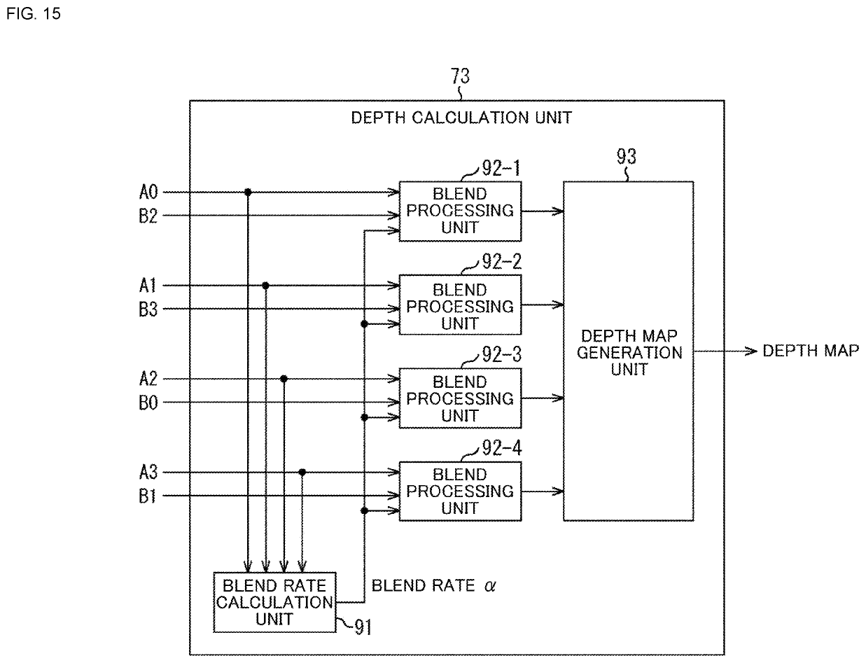

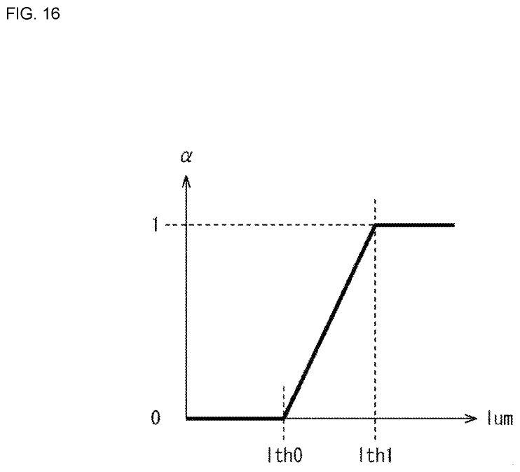

The depth calculation unit 73 acquires the detection signals A and the detection signals B with the phases 0°, 90°, 180°, and 270° of each pixel 21 stored in the frame memory 72 and calculates a depth value d that is a distance from the ranging module 11 to an object. Then, the depth calculation unit 73 generates a depth map in which a depth value is stored as a pixel value of each pixel 21 and outputs the depth map to the outside of the module. Processing of calculating the depth value d will be described later with reference to FIG. 15 and FIG. 16.

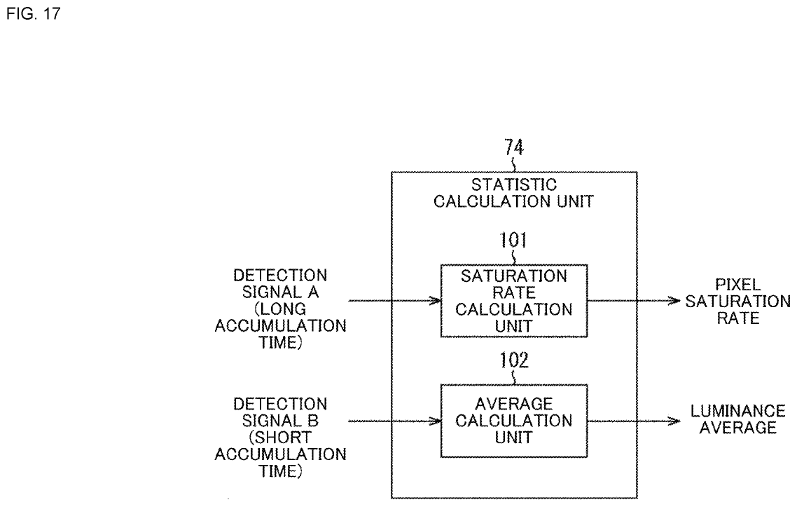

The statistic calculation unit 74 calculates statistics of pixel data of each pixel 21 supplied from the light receiving unit 15. Pixel data of the pixel 21 corresponds to a luminance value of reflected light received by the pixel 21, and the reflected light also includes ambient light such as sunlight in addition to radiated light. The statistic calculation unit 74 may calculate, for example, an average of luminance values (luminance average) of pixels, a pixel saturation rate representing a ratio of pixels in which charges (luminance values) are saturated among all pixels of the pixel array part 22, and the like. Details of statistic calculation processing performed by the statistic calculation unit 74 will be described later with reference to FIG. 17 to FIG. 20. The calculated statistics are supplied to the accumulation time calculation unit 75.

The accumulation time calculation unit 75 calculates accumulation time (long accumulation time and short accumulation time) of each pixel 21 in the next frame of the light receiving unit 15 using the statistics of the pixel data of each pixel 21 supplied from the statistic calculation unit 74 and supplies the accumulation times to the light receiving unit 15 and the correction processing unit 71. That is, the accumulation times of the pixel 21 in the next light reception are adjusted according to the statistics of the current luminance value of each pixel 21 calculated by the statistic calculation unit 74, supplied to the light receiving unit 15, and controlled.

### <6. Correction Processing in Correction Processing Unit>

Correction processing executed by the correction processing unit 71 will be described with reference to FIG. 13 and FIG. 14.

In the pixel array part 22 of the light receiving unit 15, it is difficult to completely electrically separate pixels from each other, and thus charges generated in adjacent pixels may enter a pixel and are output as a detection signal of the pixel. Further, as shown in FIG. 13, the amount of charge leakage may differs between the first tap 32A and the second tap 32B due to a difference in the physical positions of the first tap 32A (FD 32A) and the second tap 32B (FD 32B) in the pixel 21.

Therefore, the correction processing unit 71 regards each pixel 21 of the pixel array part 22 as a pixel of interest and corrects pixel data of the pixel of interest by adding results obtained by multiplying pixel data of peripheral pixels of the pixel of interest by a correction coefficient according to accumulation time to the pixel data of the pixel of interest. As the peripheral pixels, for example, pixel data of eight pixels within the range of 3×3 pixels around the pixel of interest is used, as shown in FIG. 13.

Specifically, when the position of the pixel of interest is assumed to be (x, y), as shown in FIG. 14, the correction processing unit 71 calculates a corrected detection signal A′(x, y) of the first tap 32A of the pixel of interest (x, y) and a corrected detection signal B′(x, y) of the second tap 32B of the pixel of interest (x, y) according to formula (6).

$$[ Math . 4 ]$$

$${A}^{′} ( x , y ) = A ( x , y ) + {\sum }_{i , j} c ( i , j ) * A ( x + i , y + j ) + {\sum }_{i , j} d ( i , j ) * B ( x + i , y + j ) \\ {B}^{′} ( x , y ) = B ( x , y ) + {\sum }_{i , j} e ( i , j ) * A ( x + i , y + j ) + {\sum }_{i , j} f ( i , j ) * B ( x + i , y + j ) \\ c ( i , j ) , d ( i , j ) , e ( i , j ) , f ( i , j ) : Correction coefficients ( i = - 1 , 0 , 1 , j = - 1 , 0 , 1 ) \qquad ( 6 )$$

In formula (6), c(i, j), d(i, j), e(i, j), and f(i, j) represent correction coefficients determined in advance through pre-shipment inspection of the ranging sensor 14. These correction coefficients c(i, j), d(i, j), e(i, j), and f(i, j) are determined advance depending on the duration of accumulation time and a ratio of the first accumulation time (long accumulation time) of the first tap 32A to the second accumulation time (short accumulation time) of the second tap 32B and stored in an internal memory.

The correction processing unit 71 acquires the correction coefficients c(i, j), d(i, j), e(i, j), and f(i, j) corresponding to accumulation time when corresponding pixel data has been acquired, supplied from the accumulation time calculation unit 75, from the internal memory and performs correction calculation represented by formula (6). Since a signal corresponding to charges leaking from adjacent pixels is corrected by correction processing of the correction processing unit 71, it is possible to curb an error in the depth value d calculated by the depth calculation unit 73.

### <7. Depth Calculation Processing in Depth Calculation Unit>

Depth map generation processing executed by the depth calculation unit 73 will be described with reference to FIG. 15 and FIG. 16.

FIG. 15 is a block diagram showing a detailed configuration example of the depth calculation unit 73.

The depth calculation unit 73 includes a blend rate calculation unit 91, a blend processing unit 92-1 to 92-4, and a depth map generation unit 93.

The depth calculation unit 73 acquires the detection signals A0, A1, A2, and A3 with phases 0°, 90°, 180°, and 270° of the first tap 32A and the detection signals B0, B1, B2, and B3 with the phases 0°, 90°, 180°, and 270° of the second tap 32B from the frame memory 72.

The blend rate calculation unit 91 calculates a blend rate α (hereinafter referred to as a short accumulating blend rate a) of detection signals B of the second tap 32B with respect to the detection signals A of the first tap 32A on the basis of the detection signals A0, A1, A2, and A3 of the first tap 32A detected for a long accumulation time.

Specifically, the blend rate calculation unit 91 calculates the blend rate α according to the following formulas (7) and (8).

$$[ Math . 5 ]$$

$$lum = max ( A 0 , A 1 , A 2 , A 3 ) \qquad ( 7 )$$

$$α = \{ \begin{matrix}0 & ( lum < lth 0 ) \\ ( lum - lth 0 ) / ( lth 1 - lth 0 ) & ( lth 0 ≦ lum < lth 1 ) \\ 1 & ( lth 1 ≦ lum )\end{matrix} \qquad ( 8 )$$

According to formula (7), a maximum value lum of the detection signals A0, A1, A2, and A3 with the phases 0°, 90°, 180°, and 270° of the first tap 32A is detected. Then, the short accumulating blend rate a is calculated according to formula (8) on the basis of the maximum value lum of the detection signals A.

FIG. 16 is a diagram showing processing of formula (8).

Formula (8) represents that short accumulating blend rate α=0, that is, only the detection signals A of the first tap 32A detected for a long accumulation time are adopted, when the maximum value lum of the detection signals A is less than a first threshold value lth0, that the detection signals A and B are blended according to the maximum value lum when the maximum value lum of the detection signals A is at least the first threshold value lth0 and less than a second threshold value lth1, and that short accumulating blend rate α=1, that is, only the detection signals B of the second tap 32B detected for a short accumulation time are adopted, when the maximum value lum of the detection signals A is at least the second threshold value lth1. The short accumulating blend rate α calculated according to formula (8) is supplied to the blend processing units 92-1 to 92-4.

The blend processing units 92-1 to 92-4 blend the detection signals A of the first tap 32A and the detection signals B of the second tap 32B using the short accumulating blend rate α supplied from the blend rate calculation unit 91 to calculate a detection signal C.

The blend processing unit 92-1 calculates a detection signal C0 by blending the detection signal A0 of the first tap 32A and the detection signal B2 of the second tap 32B according to the following formula (9) and supplies the detection signal C0 to the depth map generation unit 9.

The blend processing unit 92-2 calculates a detection signal C1 by blending the detection signal A1 of the first tap 32A and the detection signal B3 of the second tap 32B according to the following formula (10) and supplies the detection signal C1 to the depth map generation unit 9.

The blend processing unit 92-3 calculates a detection signal C2 by blending the detection signal A2 of the first tap 32A and the detection signal B0 of the second tap 32B according to the following formula (11) and supplies the detection signal C2 to the depth map generation unit 9.

The blend processing unit 92-4 calculates a detection signal C3 by blending the detection signal A3 of the first tap 32A and the detection signal B1 of the second tap 32B according to the following formula (12) and supplies the detection signal C3 to the depth map generation unit 9.

C0=A0×(1−α)+B2×α×β (9)

C1=A1×(1−α)+B3×α×β (10)

C2=A2×(1−α)+B0×α×β (11)

C3=A3×(1−α)+B1×α×β (12)

In formulas (9) to (12), β represents an accumulation time ratio (β=long accumulation time/short accumulation time) of the long accumulation time of the first tap 32A to the short accumulation time of the second tap 32B.

The depth map generation unit 93 calculates I and Q signals of each pixel 21 of the pixel array part 22 according to the following formula (13) and calculates a depth value d according to the aforementioned formula (2).

I=c₀−c₁₈₀=(C0−C2)

Q=c₉₀−c₂₇₀=(C1−C3) (13)

Then, the depth map generation unit 93 generates a depth map in which the depth value d is stored as a pixel value of each pixel 21 and outputs the depth map to the outside of the module.

### <8. Statistic Calculation Processing in Statistic Calculation Unit>

Next, statistic calculation processing executed by the statistic calculation unit 74 will be described with reference to FIG. 17 to FIG. 20.

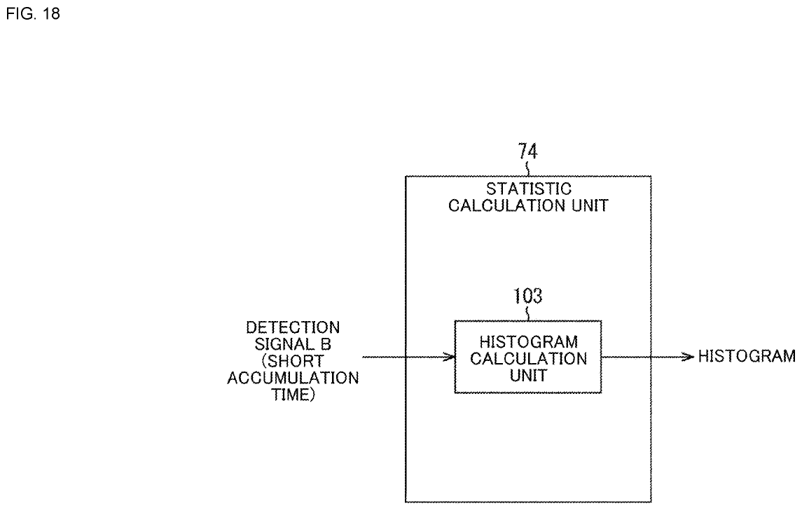

The statistic calculation unit 74 can adopt either a configuration of a first configuration example shown in FIG. 17 or a configuration of s second configuration example shown in FIG. 18.

FIG. 17 is a block diagram showing the first configuration example of the statistic calculation unit 74.

The statistic calculation unit 74 includes a saturation rate calculation unit 101 and an average calculation unit 102.

The saturation rate calculation unit 101 calculates a pixel saturation rate representing a ratio of pixels having saturated luminance values using detection signals A having a long accumulation time among pixel data of the pixels 21 of the pixel array part 22 supplied from the light receiving unit 15, that is, the detection signals A0 to A3 with phases of 0°, 90°, 180°, and 270° of the first tap 32A.

More specifically, the saturation rate calculation unit 101 calculates a long accumulating average detection signal A_AVE of the detection signals A0 to A3 of the first tap 32A with respect to all pixels of the pixel array part 22. Then, the saturation rate calculation unit 101 calculates a pixel saturation rate (=P_SAT/N) by counting the number P_SAT of pixels in which the long accumulating average detection signal A_AVE exceeds a predetermined saturation threshold value SAT_TH and dividing the counted number by the total number N of pixels of the pixel array part 22.

Meanwhile, it may be possible to count the number P_SAT of pixels in which a maximum value A_MAX or a minimum value A_MIN of the detection signals A0 to A3 of the first tap 32A exceeds the saturation threshold value SAT_TH instead of counting the number P_SAT of pixels in which the long accumulating average detection signal A_AVE of the detection signals A0 to A3 of the first tap 32A exceeds the saturation threshold value SAT_TH.

The average calculation unit 102 calculates an average of luminance values (luminance average) of all pixels of the pixel array part 22 using detection signals B having a short accumulation time, that is, detection signals B0 to B3 with phases of 0°, 90°, 180°, and 270° of the second tap 32B, among the pixel data of the pixels 21 of the pixel array part 22 supplied from the light receiving unit 15.

More specifically, the average calculation unit 102 calculates a short accumulating average detection signal B_AVE of the detection signals B0 to B3 of the second tap 32B with respect to all pixels of the pixel array part 22. Then, the average calculation unit 102 calculates a luminance average (=ΣB_AVE/N) by calculating the sum of short accumulating average detection signals B_AVE for all the pixels and dividing the sum by the total number N of pixels of the pixel array part 22.

The statistic calculation unit 74 supplies the pixel saturation rate calculated by the saturation rate calculation unit 101 and the luminance average calculated by the average calculation unit 102 to the accumulation time calculation unit 75.

FIG. 18 is a block diagram showing the second configuration example of the statistic calculation unit 74.

The statistic calculation unit 74 includes a histogram generation unit 103.

The histogram generation unit 103 generates a histogram of luminance values using detection signals B having a short accumulation time among the pixel data of the pixels 21 of the pixel array part 22 supplied from the light receiving unit 15, that is, the detection signals B0 to B3 with phases of 0°, 90°, 180°, and 270° of the second tap 32B.

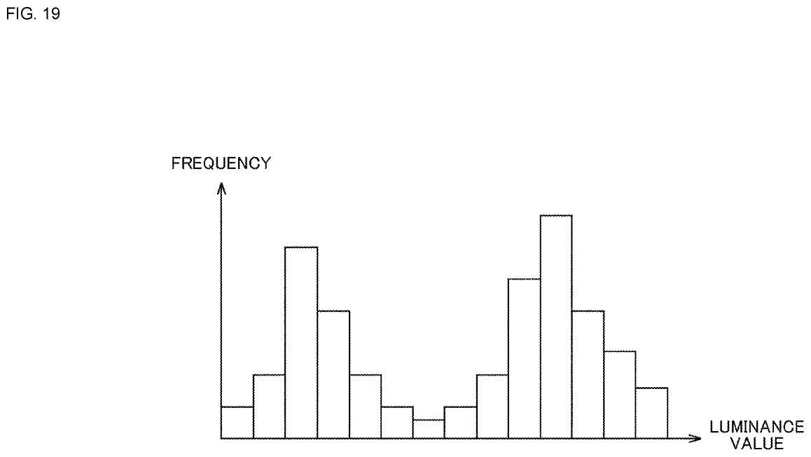

More specifically, the histogram generation unit 103 calculates a short accumulating average detection signal B_AVE of the detection signals B0 to B3 of the second tap 32B with respect to all the pixels of the pixel array part 22. Then, the histogram generation unit 103 generates (calculates) a histogram of luminance values as shown in FIG. 19 using the short accumulating average detection signal B_AVE of each pixel 21 as a luminance value. The generated histogram of the luminance values is supplied to the accumulation time calculation unit 75.

The statistic calculation unit 74 can adopt either the configuration of the first configuration example of FIG. 17 or the configuration of the second configuration example of FIG. 18, and additionally, may adopt a configuration in which both the first configuration example of FIG. 17 and the second configuration example of FIG. 18 are provided and which statistics will be used is selected according to initial settings, user settings, or the like.

### <9. Accumulation Time Calculation Processing in Accumulation Time Calculation Unit>

Next, accumulation time calculation processing executed by the accumulation time calculation unit 75 will be described.

First, accumulation time calculation processing of the accumulation time calculation unit 75 when the first configuration example of FIG. 17 is adopted for the statistic calculation unit 74 and a pixel saturation rate and a luminance average are supplied from the statistic calculation unit 74 will be described.

The accumulation time calculation unit 75 controls a long accumulation time of the next detection frame on the basis of a luminance average using detection signals B having a short accumulation time. Specifically, the accumulation time calculation unit 75 calculates the long accumulation time (updated long accumulation time) of the next detection frame according to the following formula (14).

Updated long accumulation time=(target average/luminance average value)×current short accumulation time (14)

The current short accumulation time of formula (14) is a currently set short accumulation time of the second tap 32B and the updated long accumulation time is a long accumulation time of the first tap 32A set at the time of next light reception of the light receiving unit 15. The target average is determined in advance. According to this control, the long accumulation time is controlled such that the luminance average becomes the target average, and the accumulation time calculation unit 75 controls the long accumulation time such that a dark part (a long distance and a low reflectivity) of a subject can be received with a high SN ratio.

Further, the accumulation time calculation unit 75 controls a short accumulation time of the next detection frame on the basis of a pixel saturation rate using detection signals A having a long accumulation time. Specifically, when the pixel saturation rate exceeds a target pixel saturation rate, the accumulation time calculation unit 75 controls the short accumulation time of the next detection frame (updated short accumulation time) according to the following formula (15).

Updated short accumulation time=current short accumulation time×control rate (15)

The current short accumulation time of formula (15) is a currently set short accumulation time of the second tap 32B, and the updated short accumulation time is a short accumulation time of the second tap 32B at the time of next light reception of the light receiving unit 15. The control rate is a control parameter that is a constant greater than 1.0. According to this control, the pixel saturation rate is controlled such that it becomes less than the target pixel saturation rate, and the accumulation time calculation unit 75 controls the short accumulation time such that saturated pixels are not generated as much as possible.

Next, accumulation time calculation processing of the accumulation time calculation unit 75 when the second configuration example of FIG. 18 is adopted for the statistic calculation unit 74 and a histogram of luminance values is supplied from the statistic calculation unit 74 will be described.

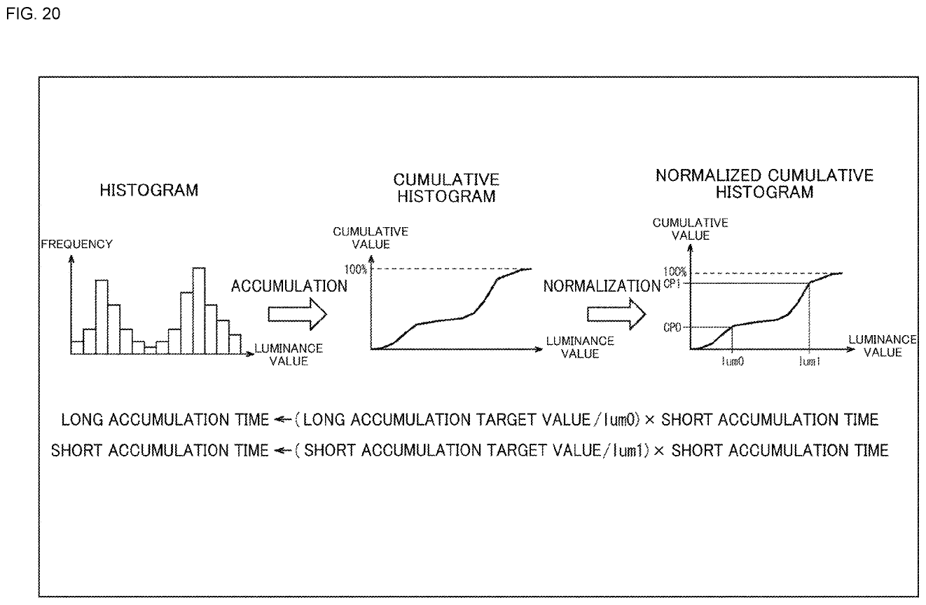

FIG. 20 is a diagram illustrating accumulation time calculation process of the accumulation time calculation unit 75 when a histogram of luminance values is supplied from the statistic calculation unit 74.

The accumulation time calculation unit 75 generates a cumulative histogram in which frequency values are accumulated from one with a lowest luminance value from the histogram of luminance values supplied from the statistic calculation unit 74. Then, the accumulation time calculation unit 75 generates a normalized cumulative histogram in which cumulative values are normalized by dividing the generated cumulative histogram by the total number of pixels.

Further, the accumulation time calculation unit 75 determines luminance values lum0 and lum1 at which cumulative values are predetermined CP0 and CP1 in the normalized cumulative histogram and determines a long accumulation time and a short accumulation time of the next detection frame according to the following formulas (16) and (17) using the luminance values lum0 and lum1.

Updated long accumulation time=(long accumulation time target value/lum0)×current short accumulation time (16)

Updated short accumulation time=(short accumulation time target value/lum1)×current short accumulation time (17)

For example, when the luminance values lum0 and lum1 with CP1 set to 90% and CP0 set to 50% are determined, bright signal levels of top 10% of the total luminance values can be controlled such that the saturation rate of the short accumulation time becomes 50%.

### <10. Measurement Processing in HDR Driving Mode>

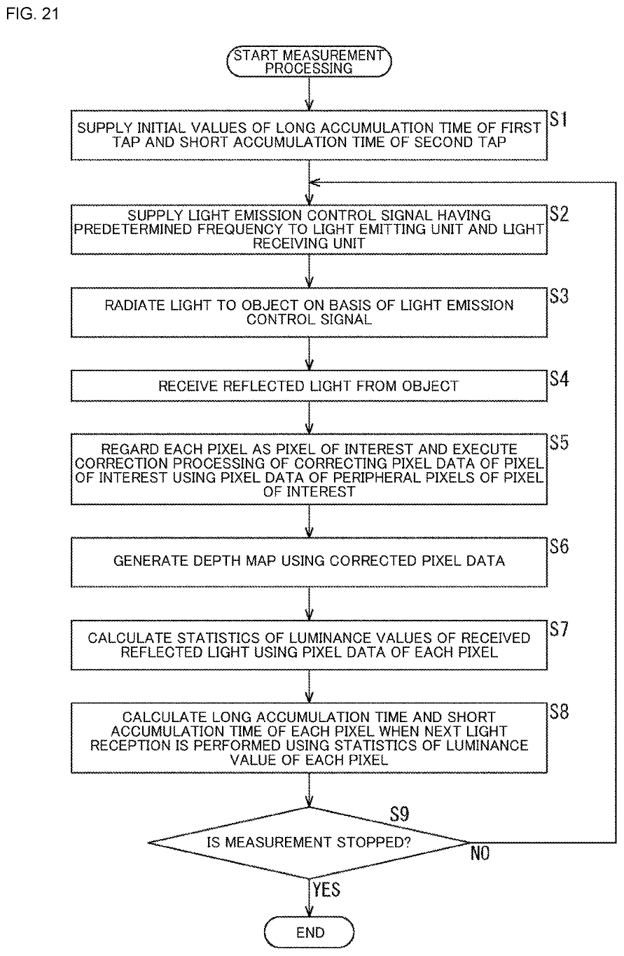

Measurement processing in which the ranging module 11 measures a distance to an object in the HDR driving mode will be described with reference to the flowchart of FIG. 21.

This processing may be started, for example, when measurement start is instructed in a state in which the HDR driving mode is set as an operation mode.

First, the signal processing unit 16 supplies initial values of the first accumulation time (long accumulation time) of the first tap 32A and the second accumulation time (short accumulation time) of the second tap 32B of each pixel 21 of the light receiving unit 15 to the light receiving unit 15 in step S1.

The light emission control unit 13 supplies a light emission control signal having a predetermined frequency (e.g., 20 MHz or the like) to the light emitting unit 12 and the light receiving unit 15 in step S2.

The light emitting unit 12 radiates radiated light to the object on the basis of the light emission control signal supplied from the light emission control unit 13 in step S3.

Each pixel 21 of the light receiving unit 15 receives reflected light from the object on the basis of control of the driving control circuit 23 in step S4. Each pixel 21 includes the first pixel circuit shown in FIG. 7 or the second pixel circuit shown in FIG. 9. Each pixel 21 controls the first accumulation time of the first tap 32A and the second accumulation time of the second tap 32B such that they become different from each other for each of four phases shifted 0°, 90°, 180°, and 270° with respect to the radiation timing of the radiated light, accumulates charges corresponding to the amount of received light, and outputs detection signals A0 to A3 and detection signals B0 to B3. The detection signals A0 to A3 and the detection signals B0 to B3 of each pixel 21 are supplied to the correction processing unit 71 and the statistic calculation unit 74 of the signal processing unit 16.

In step S5, the correction processing unit 71 executes correction processing for correcting pixel data of a pixel of interest using pixel data of peripheral pixels of the pixel of interest by regarding each pixel 21 of the pixel array part 22 as the pixel of interest. Specifically, the correction processing unit 71 multiplies the pixel data of the peripheral pixels by correction coefficients c(i, j), d(i, j), e(i, j), and f(i, j) depending on an accumulation time when the pixel data has been acquired to calculate corrected pixel data. Detection signals A and detection signals B with phases of 0°, 90°, 180°, and 270°, which are the corrected pixel data of each pixel 21, are sequentially supplied to the frame memory 72 and stored therein.

The depth calculation unit 73 generates a depth map using the corrected pixel data and outputs the depth map in step S6. More specifically, the depth calculation unit 73 acquires the detection signals A and the detection signals B with the phases of 0°, 90°, 180°, and 270° of each pixel 21 stored in the frame memory 72. Then, the depth calculation unit 73 determines a short accumulating blend rate a on the basis of the maximum value lum of the detection signals A and calculates four-phase detection signals C0 to C3 by blending the detection signals A and the detection signals B with the short accumulating blend rate α according to formulas (9) to (12). Further, the depth calculation unit 73 calculates a depth value d according to formulas (13) and (2). Then, the depth calculation unit 73 generates a depth map in which the depth value d is stored as a pixel value of each pixel 21 and outputs the depth map to the outside of the module.

In step S7, the statistic calculation unit 74 calculates statistics of luminance values of received reflected light using the pixel data of each pixel 21 supplied from the light receiving unit 15.

For example, when the statistic calculation unit 74 has the configuration of the first configuration example shown in FIG. 17, the statistic calculation unit 74 calculates a luminance average and a pixel saturation rate of each pixel 21 as statistics and supplies the luminance average and the pixel saturation rate to the accumulation time calculation unit 75.

Alternatively, when the statistic calculation unit 74 has the configuration of the second configuration example shown in FIG. 18, the statistic calculation unit 74 generates a histogram of luminance values as statistics and supplies the histogram to the accumulation time calculation unit 75.

In step S8, the accumulation time calculation unit 75 calculates and a long accumulation time and a short accumulation time of each pixel 21 when the light receiving unit 15 performs next light reception using statistics of luminance values of each pixel 21 supplied from the statistic calculation unit 74 and supplies the long accumulation time and the short accumulation time to the light receiving unit 15 and the correction processing unit 71. The driving control circuit 23 of the light receiving unit 15 controls each pixel 21 such that accumulation times of the first tap 32A and the second tap 32B of each pixel 21 become the long accumulation time and the short accumulation time supplied from the accumulation time calculation unit 75 in driving of the next frame (processing of the next step S4).

When the pixel saturation rate and the luminance average are supplied from the statistic calculation unit 74, the accumulation time calculation unit 75 calculates a long accumulation time of the next detection frame according to the aforementioned formula (14) and calculates a short accumulation time of the next detection frame according to the aforementioned formula (15).

On the other hand, when the histogram of luminance values is supplied from the statistic calculation unit 74, the accumulation time calculation unit 75 generates a normalized cumulative histogram, determines luminance values lum0 and lum1 at which cumulative values become predetermined CP0 and CP1, and calculates the long accumulation time and the short accumulation time of the next detection frame according to the aforementioned formulas (16) and (17). The calculated long accumulation time and short accumulation time are supplied to the light receiving unit 15 and also supplied to the correction processing unit 71.

In step S9, the ranging module 11 determines whether to stop measurement. For example, the ranging module 11 determines that measurement is stopped when an operation or a command to stop the measurement is supplied.

If it is determined that measurement is not stopped (measurement is continued) in step S9, processing returns to step S2 and processing of steps S2 to S9 described above are repeated.

On the other hand, if it is determined that measurement is stopped in step S9, measurement processing of FIG. 21 ends.

According to measurement processing of the ranging module 11 in the HDR driving mode described above, it is possible to calculate a depth value d on the basis of the detection signals A0 to A3 and the detection signals B0 to B3 obtained by controlling the first accumulation time of the first tap 32A and the second accumulation time of the second tap 32B of each pixel 21 such that they are different from each other to generate a depth map. By controlling the first accumulation time of the first tap 32A and the second accumulation time of the second tap 32B of each pixel 21 such that they are different from each other, it is possible to measure a distance with an expanded measurement range.

As a measurement method of a ranging sensor for expanding the measurement range, for example, a method of changing accumulation times on a frame-by-frame basis such that two taps 32 of each pixel 21 are controlled to have a long accumulation time to receive light in a first frame and two taps 32 of each pixel 21 are controlled to have a short accumulation time to receive light in a second frame is conceivable. In this measurement method, at least two frames are required in order to acquire pixel data having the long accumulation time and the short accumulation time.

According to the ranging module 11, it is possible to measure a distance with an expanded measurement range without decreasing a frame rate because pixel data having a long accumulation time and a short accumulation time can be acquired in one frame.

Alternatively, as another method of acquiring pixel data having a long accumulation time and a short accumulation time in one frame, there is a method of dividing all pixels of the pixel array part 22 into pixels 21 controlled to have a long accumulation time and pixels 21 controlled to have a short accumulation time in a spatial direction to acquire pixel data having the long accumulation time and the short accumulation time. In this measurement method, resolution deteriorates because each of the number of pixels having a long accumulation time and the number of pixels having a short accumulation time is half the total number of pixels of the pixel array part 22.

According to the ranging module 11, it is possible to perform distance measurement with an expanded measurement range without decreasing resolution because pixel data having a long accumulation time and a short accumulation time can be acquired from all pixels of the pixel array part 22.

Further, according to the ranging module 11, pixel data having a four-phase long accumulation time is acquired by one tap 32 (first tap 32A) and pixel data having a short accumulation time is also acquired by one tap 32 (second tap 32B). That is, since pixel transistors by which four-phase pixel data is detected are identical, it is not necessary to consider variation in the pixel transistors, and fixed pattern noise caused by the variation in the pixel transistors can be curbed.

### <11. Chip Configuration Example of Ranging Sensor>

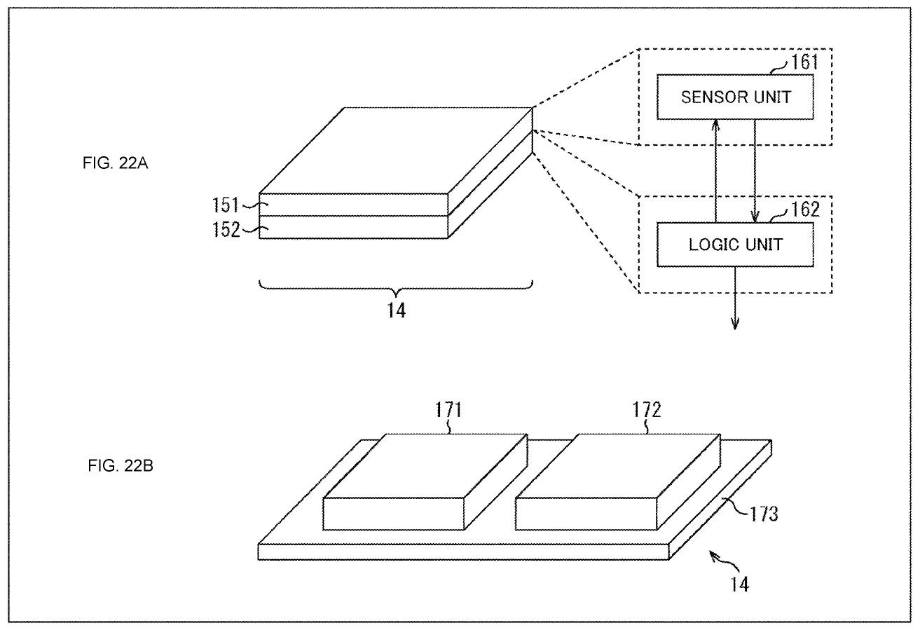

FIG. 22 is a perspective view showing a chip configuration example of the ranging sensor 14.

For example, the ranging sensor 14 can be configured as one chip in which a sensor die 151 as a plurality of dies (boards) and a logic die 152 are laminated, as shown in A of FIG. 22.

The sensor die 151 includes (a circuit as) a sensor unit 161 and the logic die 152 includes a logic unit 162.

For example, the pixel array part 22 and the driving control circuit 23 may be formed in the sensor unit 161. For example, an AD conversion unit that performs AD conversion on a detection signal, the signal processing unit 16, an input/output terminal, and the like may be formed in the logic unit 162.

Further, the ranging sensor 14 may be composed of three layers in which another logic die is laminated in addition to the sensor die 151 and the logic die 152. Of course, it may be composed of a lamination of four or more dies (boards).

Alternatively, the ranging sensor 14 may include, for example, a first chip 171 and a second chip 172, and a relay board (interposer board) 173 on which they are mounted, as shown in B of FIG. 22.

For example, the pixel array part 22 and the driving control circuit 23 may be formed on the first chip 171. An AD conversion unit that performs AD conversion on a detection signal and the signal processing unit 16 may be formed on the second chip 172.

The above-described circuit arrangement of the sensor die 151 and the logic die 152 in A of FIG. 22 and the circuit arrangement of the first chip 171 and the second chip 172 in B of FIG. 22 are merely examples and are not limited thereto. For example, in the configuration of the signal processing unit 16 shown in FIG. 12, the frame memory 72, the depth calculation unit 73, and the like may be provided outside the ranging sensor 14.

### <12. Usage Example of Ranging Module>

The present technology is not limited to application to a ranging module. That is, the present technology can be applied to all electronic devices such as smartphones, tablet terminals, mobile phones, personal computers, game machines, television receivers, wearable terminals, digital still cameras, and digital video cameras. The above-described ranging module 11 may be in a form in which the light emitting unit 12, the light emission control unit 13, and the ranging sensor 14 are packaged together, or the light emitting unit 12 and the ranging sensor 14 may be separately configured and only the ranging sensor 14 may be configured as one chip.

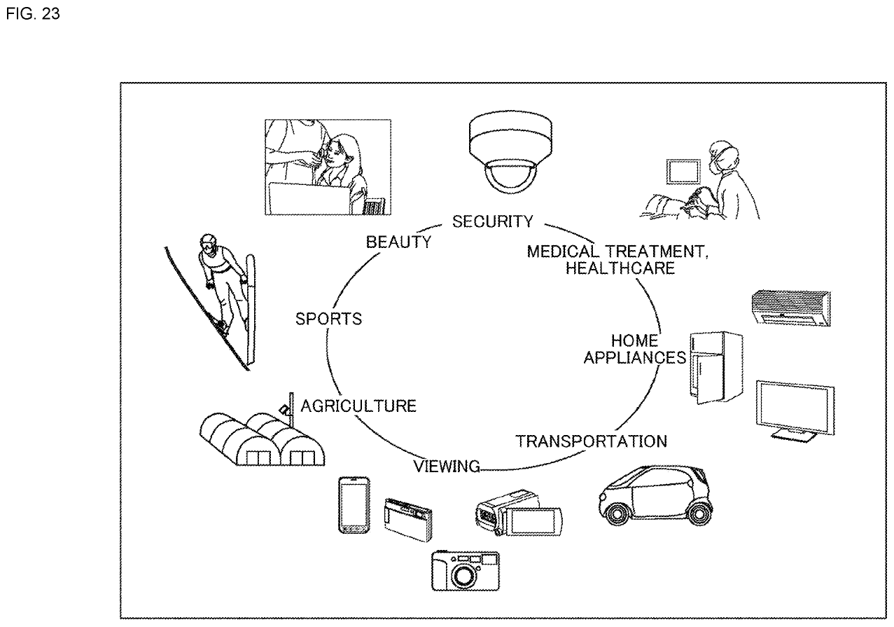

FIG. 23 is a diagram showing a usage example of the above-described ranging module 11.

The above-described ranging module 11 can be used in various cases in which light such as visible light, infrared light, ultraviolet light, or X-ray is sensed, as described below.
Devices that capture images used for viewing, such as digital cameras and mobile apparatuses with camera functions
Devices used for transportation, such as in-vehicle sensors that capture front, rear, surrounding, and interior view images of automobiles, monitoring cameras that monitor traveling vehicles and roads, ranging sensors that measure a distance between vehicles, and the like, for safe driving such as automatic stop, recognition of a driver's condition, and the like
Devices used for home appliances such as TVs, refrigerators, and air conditioners in order to capture an image of a user's gesture and perform apparatus operations according to the gesture
Devices used for medical treatment and healthcare, such as endoscopes and devices that perform angiography by receiving infrared light
Devices used for security, such as monitoring cameras for crime prevention and cameras for personal authentication
Devices used for beauty, such as a skin measuring device that captures images of the skin and a microscope that captures images of the scalp
Devices used for sports, such as action cameras and wearable cameras for sports applications
Devices used for agriculture, such as cameras for monitoring conditions of fields and crops

### <13. Example of Application to Moving Body>

The technology according to the present disclosure (the present technology) can be applied to various products. For example, the technology according to the present disclosure may be realized as a device mounted on any type of moving body such as an automobile, an electric vehicle, a hybrid electric vehicle, a motorcycle, a bicycle, a personal mobility, an airplane, a drone, a ship, and a robot.

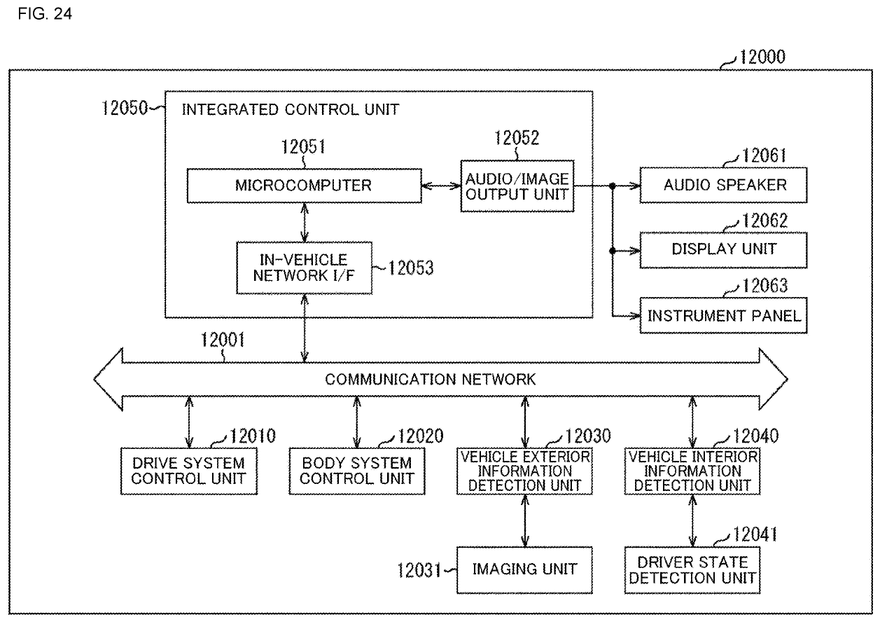

FIG. 24 is a block diagram showing a schematic configuration example of a vehicle control system that is an example of a moving body control system to which the technology according to the present disclosure can be applied.

A vehicle control system 12000 includes a plurality of electronic control units connected via a communication network 12001. In the example illustrated in FIG. 24, the vehicle control system 12000 includes a drive system control unit 12010, a body system control unit 12020, a vehicle exterior information detection unit 12030, a vehicle interior information detection unit 12040, and an integrated control unit 12050. Further, a microcomputer 12051, an audio/image output unit 12052, and an in-vehicle network interface (I/F) 12053 are illustrated as a functional configuration of the integrated control unit 12050.

The drive system control unit 12010 controls operations of devices related to a drive system of a vehicle according to various programs. For example, the drive system control unit 12010 functions as a driving force generator for generating a driving force of a vehicle such as an internal combustion engine or a driving motor, a driving force transmission mechanism for transmitting a driving force to wheels, a steering mechanism for adjusting a turning angle of a vehicle, and a control device such as a braking device that generates a braking force of a vehicle.

The body system control unit 12020 controls operations of various devices mounted in the vehicle body according to various programs. For example, the body system control unit 12020 functions as a control device of a keyless entry system, a smart key system, a power window device, or various lamps such as a head lamp, a back lamp, a brake lamp, a turn signal, or a fog lamp. In this case, radio waves transmitted from a portable device that substitutes for a key or signals of various switches can be input to the body system control unit 12020. The body system control unit 12020 receives input of these radio waves or signals and controls a door lock device, a power window device, a lamp, and the like of the vehicle.

The vehicle exterior information detection unit 12030 detects information on the exterior of the vehicle in which the vehicle control system 12000 is mounted. For example, an imaging unit 12031 is connected to the vehicle exterior information detection unit 12030. The vehicle exterior information detection unit 12030 causes the imaging unit 12031 to capture an image of the exterior of the vehicle and receives the captured image. The vehicle exterior information detection unit 12030 may perform object detection processing or distance detection processing for persons, vehicles, obstacles, signs, or text on a road surface on the basis of the received image.

The imaging unit 12031 is an optical sensor that receives light and outputs an electrical signal corresponding to the amount of the received light. The imaging unit 12031 can also output the electrical signal as an image and ranging information. In addition, light received by the imaging unit 12031 may be visible light, or may be invisible light such as infrared light.

The vehicle interior information detection unit 12040 detects information on the interior of the vehicle. For example, a driver state detection unit 12041 that detects a driver's state is connected to the vehicle interior information detection unit 12040. The driver state detection unit 12041 includes, for example, a camera that captures an image of the driver, and the vehicle interior information detection unit 12040 may calculate a degree of fatigue or concentration of the driver or may determine whether or not the driver is dozing on the basis of detection information input from the driver state detection unit 12041.

The microcomputer 12051 can calculate a control target value of the driving force generation device, the steering mechanism, or the braking device on the basis of the information inside and outside the vehicle acquired by the vehicle exterior information detection unit 12030 or the vehicle interior information detection unit 12040, and output a control command to the drive system control unit 12010. For example, the microcomputer 12051 can perform cooperative control aiming at realizing functions of advanced driver assistance system (ADAS) including vehicle collision avoidance or impact mitigation, follow-up traveling based on an inter-vehicle distance, vehicle speed maintenance traveling, vehicle collision warning, vehicle lane deviation warning, and the like.

Further, the microcomputer 12051 can perform coordinated control for the purpose of automated driving or the like in which autonomous travel is performed without depending on an operation of a driver by controlling the driving force generator, the steering mechanism, the braking device, and the like on the basis of information regarding the vicinity of the vehicle acquired by the vehicle exterior information detection unit 12030 or the vehicle interior information detection unit 12040.

Further, the microcomputer 12051 can output a control command to the body system control unit 12020 on the basis of information regarding the vehicle exterior acquired by the vehicle exterior information detection unit 12030. For example, the microcomputer 12051 can perform coordinated control for the purpose of achieving anti-glare such as switching of a high beam to a low beam by controlling the head lamp in accordance with a position of a preceding vehicle or an oncoming vehicle detected by the vehicle exterior information detection unit 12030.

The audio/image output unit 12052 transmits an output signal of at least one of audio and an image to an output device capable of visually or audibly notifying an occupant of a vehicle or the outside of the vehicle of information. In the example illustrated in FIG. 24, an audio speaker 12061, a display unit 12062, and an instrument panel 12063 are illustrated as output devices. The display unit 12062 may include, for example, at least one of an on-board display and a heads-up display.

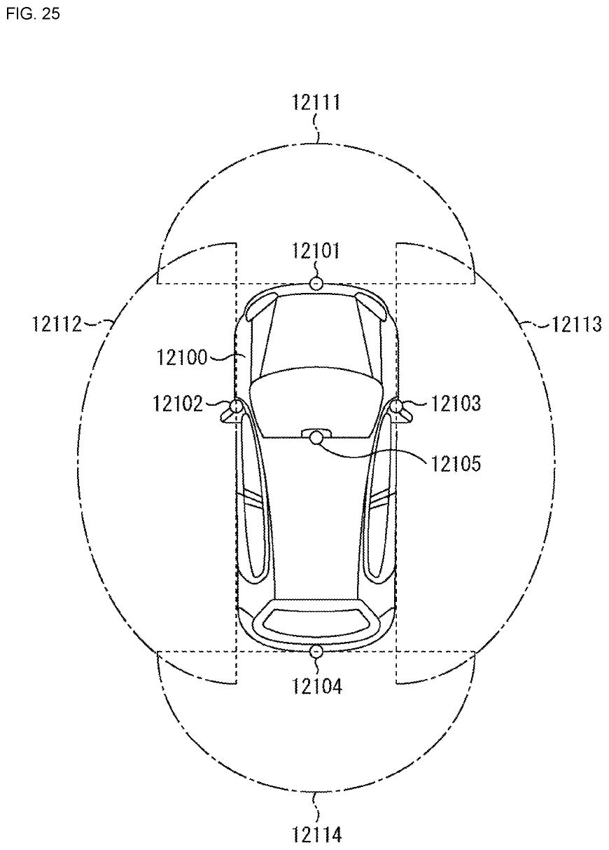

FIG. 25 is a diagram showing an example of an installation position of the imaging unit 12031.

In FIG. 25, a vehicle 12100 includes imaging units 12101, 12102, 12103, 12104, and 12105 as the imaging unit 12031.

The imaging units 12101, 12102, 12103, 12104, and 12105 may be provided at positions such as a front nose, side-view mirrors, a rear bumper, a back door, and an upper part of a windshield in a vehicle interior of the vehicle 12100, for example. The imaging unit 12101 provided at the front nose and the imaging unit 12105 provided at an upper part of the windshield inside the vehicle mainly obtain front view images of the vehicle 12100. The imaging units 12102 and 12103 provided in the side-view mirrors mainly obtain side view images of the vehicle 12100. The imaging unit 12104 provided in the rear bumper or the back door mainly obtains a rear view image of the vehicle 12100. The front view images acquired by the imaging units 12101 and 12105 are mainly used for detection of preceding vehicles, pedestrians, obstacles, traffic signals, traffic signs, lanes, and the like.

FIG. 25 shows an example of imaging ranges of the imaging units 12101 to 12104. An imaging range 12111 indicates an imaging range of the imaging unit 12101 provided at the front nose, imaging ranges 12112 and 12113 respectively indicate the imaging ranges of the imaging units 12102 and 12103 provided at the side mirrors, and an imaging range 12114 indicates the imaging range of the imaging unit 12104 provided at the rear bumper or the back door. For example, a bird's-eye view image of the vehicle 12100 as viewed from above can be obtained by superimposition of image data captured by the imaging units 12101 to 12104.

At least one of the imaging units 12101 to 12104 may have a function for obtaining distance information. For example, at least one of the imaging units 12101 to 12104 may be a stereo camera constituted by a plurality of image sensors or may be an imaging element having pixels for phase difference detection.

For example, the microcomputer 12051 can extract, particularly, a closest three-dimensional object on a path through which the vehicle 12100 is traveling, which is a three-dimensional object traveling at a predetermined speed (for example, 0 km/h or higher) in the substantially same direction as the vehicle 12100, as a preceding vehicle by acquiring a distance to each of three-dimensional objects in the imaging ranges 12111 to 12114 and temporal change in the distance (a relative speed with respect to the vehicle 12100) on the basis of distance information obtained from the imaging units 12101 to 12104. Furthermore, the microcomputer 12051 can set an inter-vehicle distance to be secured in front of the preceding vehicle in advance, and perform automatic brake control (including following stop control), automatic acceleration control (including following start control), and the like. Thus, it is possible to perform cooperative control for the purpose of, for example, autonomous driving in which the vehicle autonomously travels without requiring the driver to perform operations.

For example, the microcomputer 12051 can classify and extract three-dimensional object data regarding three-dimensional objects into two-wheeled vehicles, ordinary vehicles, large vehicles, pedestrians, and other three-dimensional objects such as utility poles on the basis of distance information obtained from the imaging units 12101 to 12104 and use the three-dimensional object data for automatic avoidance of obstacles. For example, the microcomputer 12051 classifies obstacles in the vicinity of the vehicle 12100 into obstacles that can be visually recognized by the driver of the vehicle 12100 and obstacles that are difficult to visually recognize. Then, the microcomputer 12051 can determine a risk of collision indicating the degree of risk of collision with each obstacle, and can perform driving assistance for collision avoidance by outputting a warning to a driver through the audio speaker 12061 or the display unit 12062 and performing forced deceleration or avoidance steering through the drive system control unit 12010 when the risk of collision has a value equal to or greater than a set value and there is a possibility of collision.

At least one of the imaging units 12101 to 12104 may be an infrared camera that detects infrared light. For example, the microcomputer 12051 can recognize a pedestrian by determining whether or not a pedestrian is present in images captured by the imaging units 12101 to 12104. Such recognition of a pedestrian is performed by, for example, a procedure of extracting a feature point in captured images of the imaging units 12101 to 12104 serving as infrared cameras, and a procedure of performing pattern matching processing on a series of feature points indicating the contour of an object to determine whether or not the object is a pedestrian. When the microcomputer 12051 determines that a pedestrian is present in the captured images of the imaging units 12101 to 12104 and recognizes the pedestrian, the audio/image output unit 12052 controls the display unit 12062 such that a square contour line for emphasis is superimposed on the recognized pedestrian and is displayed. In addition, the audio/image output unit 12052 may control the display unit 12062 so that an icon or the like indicating a pedestrian is displayed at a desired position.

An example of the vehicle control system to which the technology according to the present disclosure can be applied has been described above. The technology according to the present disclosure can be applied to the imaging unit 12031 and the like in the above-described configuration. Specifically, the ranging module 11 of FIG. 1 can be applied to the imaging unit 12031, for example. The imaging unit 12031 may be LIDAR, for example, and is used to detect an object around the vehicle 12100 and a distance to the object. By applying the technology according to the present disclosure to the imaging unit 12031, the measurement range of the object around the vehicle 12100 and the distance to the object is expanded. As a result, for example, vehicle collision warning can be performed at an appropriate timing and a traffic accident can be prevented.

In the present specification, a system is a collection of a plurality of constituent elements (devices, modules (components), or the like) and all the constituent elements may be located or not located in the same casing. Therefore, a plurality of devices housed in separate housings and connected via a network, and one device in which a plurality of modules are housed in one housing are both systems.

In addition, embodiments of the present technology are not limited to the above-described embodiments, and various modifications can be made without departing from the gist of the present technology.

The effects described in the present specification are merely examples and are not limited, and there may be effects other than those described in the present specification.

The present technology can employ the following configurations.

(1) A light receiving device including a pixel having a photoelectric conversion unit that photoelectrically converts incident light to generate charges, a first charge accumulation unit that accumulates first charges generated in the photoelectric conversion unit for a first accumulation time, and a second charge accumulation unit that accumulates second charges generated in the photoelectric conversion unit for a second accumulation time different from the first accumulation time.

(2) The light receiving device according to (1), wherein the pixel further has a first reset transistor that discharges the first charges of the first charge accumulation unit, and a second reset transistor that discharges the second charges of the second charge accumulation unit, and the first accumulation time and the second accumulation time are controlled to be different times by changing a time in which the first reset transistor is in an active state and a time in which the second reset transistor is in an active state.

(3) The light receiving device according to (1) or (2), further including a discharge transistor that discharges the charges of the photoelectric conversion unit, wherein the discharge transistor is controlled to be in an active state in a period in which charges are accumulated in the second charge accumulation unit.

(4) The light receiving device according to (3), wherein accumulation of the second charges in the second charge accumulation unit is executed once with respect to accumulation of the first charges a plurality of times in the first charge accumulation unit.

(5) The light receiving device according to (4), wherein the discharge transistor is controlled to be in an active state between accumulation of the second charges in the second charge accumulation unit and accumulation of the first charges in the first charge accumulation unit.

(6) The light receiving device according to any one of (1) to (5), wherein the light incident on the pixel is reflected light obtained by reflection of radiated light from an object, and the pixel accumulates the first charges and the second charges for each of four phases with respect to radiation timing of the radiated light.

(7) The light receiving device according to any one of (1) to (6), further including a pixel array part in which a plurality of the pixels are arranged in a matrix form, and a correction processing unit that corrects pixel data of the pixel using pixel data of peripheral pixels of the pixel.

(8) The light receiving device according to (7), wherein the correction processing unit corrects the pixel data of the pixel by adding multiplication results obtained by multiplying the pixel data of the peripheral pixels of the pixel by correction coefficients depending on an accumulation time to the pixel data of the pixel.

(9) The light receiving device according to any one of (1) to (8), further including a pixel array part in which a plurality of the pixels are arranged in a matrix form, and a statistic calculation unit that calculates statistics of pixel data of a plurality of the pixels.

(10) The light receiving device according to (9), wherein the statistic calculation unit calculates a pixel saturation rate, which is a ratio of pixels in which the charges are saturated, and a luminance average of a plurality of the pixels as the statistics.

(11) The light receiving device according to (10), wherein the pixel saturation rate is calculated using the pixel data having the first accumulation time of the pixel, and the luminance average is calculated using the pixel data having the second accumulation time of the pixel.

(12) The light receiving device according to any one of (9) to (11), wherein the statistic calculation unit calculates a histogram of pixel data of a plurality of the pixels.

(13) The light receiving device according to any one of (9) to (12), further including an accumulation time calculation unit that calculates the first accumulation time and the second accumulation time of a next frame on the basis of statistics of the pixel data of a plurality of the pixels.

(14) The light receiving device according to (13), further including a driving control unit that drives the pixel such that accumulation time becomes the first accumulation time and the second accumulation time.

(15) A method for driving a light receiving device including a pixel having a photoelectric conversion unit, a first charge accumulation unit, and a second charge accumulation unit, by a driving control unit of the light receiving device, including

accumulating first charges generated in the photoelectric conversion unit for a first accumulation time in the first charge accumulation unit, and accumulating second charges generated in the photoelectric conversion unit for a second accumulation time different from the first accumulation time in the second charge accumulation unit.

### REFERENCE SIGNS LIST

11 Ranging module
12 Light emitting unit
13 Light emission control unit
14 Ranging sensor
15 Light receiving unit
16 Signal processing unit
21 Pixel
22 Pixel array part
23 Driving control circuit
31 Photodiode (PD)
32A FD (first tap)
32B FD (second tap)
33 Transfer transistor
34 Switching transistor
35 Reset transistor
36 Amplification transistor
37 Selection transistor
38 Discharge transistor
51, 52, 53, 54, 55 Signal line
56 Vertical signal line
71 Correction processing unit
72 Frame memory
73 Depth calculation unit
74 Statistic calculation unit
75 Accumulation time calculation unit
91 Blend rate calculation unit
92-1, 92-2, 92-3, 92-4 Blend processing unit
93 Depth map generation unit
101 Saturation rate calculation unit
102 Average calculation unit
103 Histogram generation unit

1. A light receiving device comprising a pixel including: a photoelectric conversion unit that photoelectrically converts incident light to generate charges;
a first charge accumulation unit that accumulates first charges generated in the photoelectric conversion unit for a first accumulation time; and
a second charge accumulation unit that accumulates second charges generated in the photoelectric conversion unit for a second accumulation time different from the first accumulation time.

2. The light receiving device according to claim 1, wherein the pixel further includes:
a first reset transistor that discharges the first charges of the first charge accumulation unit; and
a second reset transistor that discharges the second charges of the second charge accumulation unit, and
the first accumulation time and the second accumulation time are controlled to be different times by changing a time in which the first reset transistor is in an active state and a time in which the second reset transistor is in an active state.

3. The light receiving device according to claim 1, further comprising a discharge transistor that discharges the charges of the photoelectric conversion unit, wherein the discharge transistor is controlled to be in an active state in a period in which charges are accumulated in the second charge accumulation unit.

4. The light receiving device according to claim 3, wherein accumulation of the second charges in the second charge accumulation unit is executed once with respect to accumulation of the first charges a plurality of times in the first charge accumulation unit.

5. The light receiving device according to claim 4, wherein the discharge transistor is controlled to be in an active state between accumulation of the second charges in the second charge accumulation unit and accumulation of the first charges in the first charge accumulation unit.

6. The light receiving device according to claim 1, wherein the light incident on the pixel is reflected light obtained by reflection of radiated light from an object, and the pixel accumulates the first charges and the second charges for each of four phases with respect to radiation timing of the radiated light.

7. The light receiving device according to claim 1, further comprising: a pixel array part in which a plurality of the pixels are arranged in a matrix form; and
a correction processing unit that corrects pixel data of the pixel using pixel data of peripheral pixels of the pixel.

8. The light receiving device according to claim 7, wherein the correction processing unit corrects the pixel data of the pixel by adding multiplication results obtained by multiplying the pixel data of the peripheral pixels of the pixel by correction coefficients depending on an accumulation time to the pixel data of the pixel.

9. The light receiving device according to claim 1, further comprising: a pixel array part in which a plurality of the pixels are arranged in a matrix form; and
a statistic calculation unit that calculates statistics of pixel data of a plurality of the pixels.

10. The light receiving device according to claim 9, wherein the statistic calculation unit calculates a pixel saturation rate, which is a ratio of pixels in which the charges are saturated, and a luminance average of a plurality of the pixels as the statistics.

11. The light receiving device according to claim 10, wherein the pixel saturation rate is calculated using the pixel data having the first accumulation time of the pixel, and the luminance average is calculated using the pixel data having the second accumulation time of the pixel.

12. The light receiving device according to claim 9, wherein the statistic calculation unit calculates a histogram of pixel data of a plurality of the pixels.

13. The light receiving device according to claim 9, further comprising an accumulation time calculation unit that calculates the first accumulation time and the second accumulation time of a next frame on the basis of statistics of the pixel data of a plurality of the pixels.

14. The light receiving device according to claim 13, further comprising a driving control unit that drives the pixel such that accumulation time becomes the first accumulation time and the second accumulation time.

15. A method for driving a light receiving device including a pixel having a photoelectric conversion unit, a first charge accumulation unit, and a second charge accumulation unit, by a driving control unit of the light receiving device, comprising:
accumulating first charges generated in the photoelectric conversion unit for a first accumulation time in the first charge accumulation unit; and
accumulating second charges generated in the photoelectric conversion unit for a second accumulation time different from the first accumulation time in the second charge accumulation unit.
